(19) United States
(12) Patent Application Publication
(10) Pub. No.: US 2026/0157104 A1
(43) Pub. Date: Jun. 4, 2026

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventors: Hyung Keun PARK, Yongin-si (KR); Hyun Do SHIN, Yongin-si (KR); Ju Ri NAM, Yongin-si (KR); Min Kyu YEO, Yongin-si (KR); Byung Su OH, Yongin-si (KR)

(73) Assignee: Samsung Display Co., LTD., Yongin-si (KR)

(21) Appl. No.: 19/277,945

(22) Filed: Jul. 23, 2025

(30) Foreign Application Priority Data
Dec. 4, 2024 (KR) 10-2024-0178405

(51) Int. Cl. H10K 59/88; H10K 59/12; H10K 59/131; H10K 59/80

(52) U.S. Cl. CPC H10K 59/88; H10K 59/1201; H10K 59/131; H10K 59/873

(57) ABSTRACT

A display device, a method of manufacturing the same, and an electronic device are provided. The display device includes a circuit layer disposed on the substrate, a pixel electrode disposed on the circuit layer in an emission area, an auxiliary electrode disposed on the circuit layer in a non-emission area and spaced apart from the pixel electrode, a dummy electrode disposed on the circuit layer in the non-emission area and spaced apart from the auxiliary electrode, a light emitting layer disposed on the pixel electrode, the auxiliary electrode and the dummy electrode and comprising openings overlapping the auxiliary electrode and a common electrode disposed on the light emitting layer and electrically connected to the auxiliary electrode through the openings, wherein the dummy electrode has a loop shape having a first line width.

### CROSS-REFERENCE TO RELATED APPLICATION(S)

This application claims the benefit of Korean Patent Application No. 10-2024-0178405,

filed on Dec. 4, 2024, in the Korean Intellectual Property Office, the disclosure of which is incorporated herein in its entirety by reference.

### BACKGROUND

### 1. Technical Field

The disclosure relates to a display device, a method of manufacturing the same, and an electronic device.

### 2. Description of the Related Art

Display devices are becoming increasingly important with the development of multimedia. Accordingly, various display devices such as liquid crystal display devices (LCDs) and organic light emitting diode display devices (OLEDs) are being developed.

Of the display devices, a self-light emitting display device includes a self-light emitting element such as an organic light emitting diode. The self-light emitting element may include two electrodes facing each other and a light emitting layer interposed between the two electrodes. In case that the self-light emitting element is an organic light emitting diode, electrons and holes provided from the two electrodes may be recombined in the light emitting layer to generate excitons. As the generated excitons change from an excited state to a ground state, light may be emitted.

Since self-light emitting display devices do not need a light source such as a backlight unit, they are low in power consumption, can be made lightweight and thin, and have a wide viewing angle, high luminance and contrast and fast response speed. Due to these high-quality characteristics, the self-light emitting display devices are drawing attention as next-generation display devices.

### SUMMARY

Aspects of the disclosure provide a display device which can reduce random pixel failures, a method of manufacturing the display device, and an electronic device applying the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, the display device includes a substrate, a circuit layer disposed on the substrate, a pixel electrode disposed on the circuit layer in an emission area, an auxiliary electrode disposed on the circuit layer in a non-emission area and spaced apart from the pixel electrode, a dummy electrode disposed in the non-emission area on the circuit layer and spaced apart from the auxiliary electrode, a light emitting layer disposed on the pixel electrode, the auxiliary electrode and the dummy electrode and including openings overlapping the auxiliary electrode and a common electrode disposed on the light emitting layer and electrically connected to the auxiliary electrode through the openings, wherein the dummy electrode has a loop shape having a first line width.

According to one or more embodiments, the first line width may be in a range of about 6 μm to about 12 μm.

According to one or more embodiments, the dummy electrode may have an inner diameter and an outer diameter, and the outer diameter of the dummy electrode may be substantially equal to a diameter of the auxiliary electrode.

According to one or more embodiments, the dummy electrode and the auxiliary electrode may be disposed on a same layer.

According to one or more embodiments, the dummy electrode and the auxiliary electrode may be arranged in a first direction and a second direction and may be alternately disposed in the first direction.

According to one or more embodiments, the display device may further include an auxiliary line extending along the first direction and connecting the dummy electrode and the auxiliary electrode.

According to one or more embodiments, the auxiliary line, the dummy electrode, and the auxiliary electrode may be disposed in the same layer.

According to one or more embodiments, the pixel electrode, the dummy electrode, and the auxiliary electrode may be disposed on a same layer.

According to one or more embodiments, an area of the dummy electrode may be smaller than an area of the auxiliary electrode.

According to one or more embodiments, an overlap area between the dummy electrode and the common electrode may be smaller than an overlap area between the auxiliary electrode and the common electrode.

According to one or more embodiments, a ratio of the number of dummy electrodes to the number of auxiliary electrodes may be about 1:1.

According to one or more embodiments, the dummy electrode may have an inner diameter and an outer diameter, the outer diameter of the dummy electrode may define an opening area, and the circuit layer, the light emitting layer and the common electrode may sequentially overlap in the opening area.

According to one or more embodiments, a portion of the auxiliary electrode may be exposed by the openings of the light emitting layer, and the common electrode may be disposed on the exposed portion of the auxiliary electrode.

According to one or more embodiments, the pixel electrode may be electrically connected to a first voltage line, and the auxiliary electrode may be electrically connected to a second voltage line which is a lower potential voltage than a first voltage.

According to one or more embodiments, the display device may further include an encapsulation layer disposed on the common electrode, wherein the encapsulation layer may include a plurality of encapsulating inorganic layers and at least one encapsulating organic layer disposed between the plurality of encapsulating inorganic layers.

According to another aspect of the disclosure, method of manufacturing a display device, the method includes forming a pixel electrode, an auxiliary electrode, a dummy electrode and an auxiliary line on a circuit layer disposed on a substrate and forming the dummy electrode in a loop shape, forming a pixel defining layer between the pixel electrode, the auxiliary electrode, and the dummy electrode, forming a light emitting layer on the pixel electrode, the auxiliary electrode, and the dummy electrode, forming an opening area through a laser drilling process on a portion of the light emitting layer on the auxiliary electrode and forming a common electrode on the pixel electrode, the auxiliary electrode, and the dummy electrode, wherein the dummy electrode and the common electrode are electrically connected through the opening area.

According to one or more embodiments, in the forming of the pixel electrode, the auxiliary electrode, the dummy electrode and the auxiliary line on the circuit layer disposed on the substrate and the forming of the dummy electrode in the loop shape, a conductive material may be deposited on the entire surface of the circuit layer and selectively patterned using a photolithography method to simultaneously form the pixel electrode, the auxiliary electrode, the dummy electrode, and the auxiliary line.

According to one or more embodiments, wherein in the forming of the dummy electrode in the loop shape, the dummy electrode may have a first line width, and the first line width is in a range of about 6 μm to about 12 μm.

According to one or more embodiments, the method may further include forming an encapsulation layer on the common electrode, wherein the encapsulation layer may include a plurality of encapsulating inorganic layers and at least one encapsulating organic layer disposed between the plurality of encapsulating inorganic layers.

According to another aspect of the disclosure, an electronic device includes a memory, a display device and a processor connected to the memory and the display device and that executes commands included in the memory, wherein the display device includes a substrate, a circuit layer disposed on the substrate, a pixel electrode disposed on the circuit layer in a first area, an auxiliary electrode disposed on the circuit layer in a second area and spaced apart from the pixel electrode, a dummy electrode disposed on the circuit layer in a third area and spaced apart from the auxiliary electrode, an organic layer disposed on the pixel electrode, the auxiliary electrode and the dummy electrode and including openings overlapping the auxiliary electrode and a common electrode disposed on the organic layer and electrically connected to the auxiliary electrode through the openings, wherein the dummy electrode has a loop shape having a first line width.

According to a display device according to an embodiment, the overlap area of the dummy electrode and the common electrode can be made smaller than the overlapping area of the dummy electrode and the common electrode to reduce random pixel defects.

In addition, the shape of the dummy electrode is a ring, so that the arrangement of the dummy electrode area of the dummy electrode is not visible.

### BRIEF DESCRIPTION OF THE DRAWINGS

These and/or other aspects will become apparent and more readily appreciated from

the following description of the embodiments, taken in conjunction with the accompanying drawings in which:

FIG. 1 is a schematic perspective view of a display device according to an embodiment;

FIG. 2 is a schematic cross-sectional view taken along line X1-X1′ of FIG. 1;

FIG. 3 is a schematic cross-sectional view of a display device according to an embodiment;

FIG. 4 is a schematic plan view illustrating a state in which connection films are attached to wiring pads of the display device according to the embodiment of FIG. 1;

FIG. 5 is a schematic plan view illustrating a state in which the connection films are not attached to the wiring pads of the display device according to the embodiment of FIG. 1;

FIG. 6 is a schematic plan view of a part of a display area of a display substrate according to an embodiment;

FIG. 7 is a schematic cross-sectional view taken along line X2-X2′ of FIG. 6;

FIG. 8 is a schematic diagram of an equivalent circuit of a pixel according to an embodiment;

FIG. 9 is a layout view illustrating auxiliary electrodes and dummy electrodes of the display area of FIG. 6 according to embodiments;

FIG. 10 is a schematic cross-sectional view taken along line X3-X3′ of FIG. 9 according to an embodiment;

FIG. 11 is a schematic cross-sectional view taken along line X4-X4′ of FIG. 9 according to an embodiment;

FIG. 12 is a schematic cross-sectional view taken along lines X5-X5′ and X5′-X5″ of FIG. 9 according to an embodiment;

FIG. 13 is a flowchart illustrating a method of manufacturing a display device according to an embodiment;

FIGS. 14 through 18 are schematic cross-sectional views of a display substrate for explaining the method of manufacturing the display device according to the embodiment;

FIG. 19 is a layout view illustrating auxiliary electrodes and dummy electrodes of the display area of FIG. 6 according to an embodiment;

FIG. 20 is a layout view of a display panel not including dummy electrodes;

FIG. 21 is a layout view of a display panel not including dummy electrodes;

FIG. 22 is a graph illustrating the probability of random pixel failure in various embodiments;

FIG. 23 is a schematic block diagram of an electronic device according to an embodiment; and

FIG. 24 is a schematic diagram of an electronic device according to various embodiments.

### DETAILED DESCRIPTION OF THE EMBODIMENTS

Aspects and features of embodiments and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the disclosure will be thorough and complete, and will fully convey the aspects and features of the disclosure to those skilled in the art. Accordingly, processes, elements, and techniques that are not necessary to those having ordinary skill in the art for a complete understanding of the aspects and features of the disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are illustrative for the purpose of describing embodiments according to the disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments refers to “one or more embodiments”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments refers to “one or more embodiments.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than about 1.0 and a maximum value equal to or less than about 10.0, such as, for example, about 2.4 to about 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic or electric devices and/or any other relevant devices or components according to one or more embodiments described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the specification, and should not be interpreted in an idealized or overly formal sense, unless expressly so defined herein.

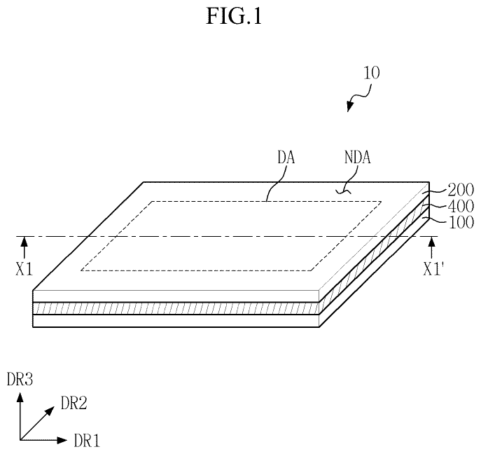

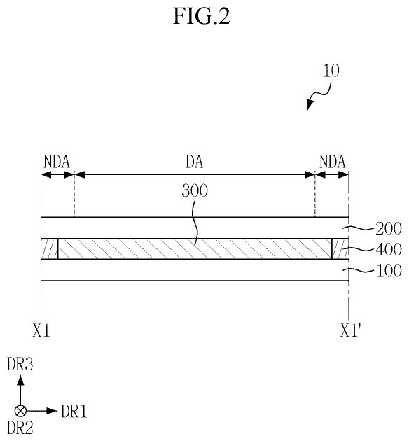

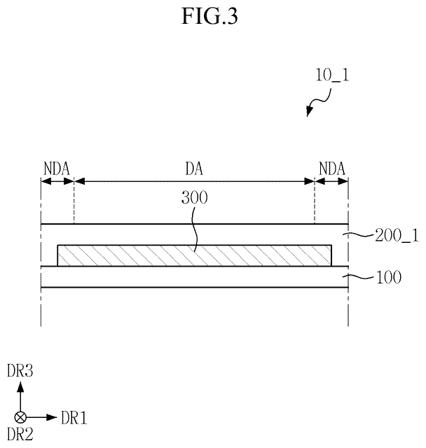

FIG. 1 is a schematic perspective view of a display device 10 according to an embodiment. FIG. 2 is a schematic cross-sectional view taken along line X1-X1′ of FIG. 1. FIG. 3 is a schematic cross-sectional view of a display device 10_1 according to an embodiment.

Referring to FIGS. 1 through 3, the display device 10 may be applied to various electronic devices including small and medium-sized electronic equipment such as tablet personal computers (PCs), smartphones, car navigation units, cameras, center information displays (CIDs) provided in vehicles, wristwatch type electronic devices, personal digital assistants (PDAs), portable multimedia players (PMPs) and game consoles and medium and large-sized electronic equipment such as televisions, outdoor billboards, monitors, PCs and notebook computers. These are presented as examples, and the display device 10 may also be employed in other electronic devices as long as not departing from the spirit of the disclosure.

In an embodiment, the display device 10 may be rectangular in plan view. The display device 10 may include two long sides extending in a first direction DR1 and two short sides extending in a second direction DR2 crossing the first direction DR1. Each corner where a long side of the display device 10 meets a short side may be right-angled. However, embodiments are not limited thereto, and each corner may also form a curved surface. In an embodiment, the long sides may extend in the second direction DR2, and the short sides may extend in the first direction DR1. The planar shape of the display device 10 is not limited to the above example and may also be a circular shape or other shapes.

In the drawings, the first direction DR1 and the second direction DR2 are horizontal directions crossing each other. For example, the first direction DR1 and the second direction DR2 may be orthogonal to each other. In addition, a third direction DR3 may cross the first direction DR1 and the second direction DR2, for example, may be a vertical direction orthogonal to the first direction DR1 and the second direction DR2. Unless otherwise defined, in the present specification, a direction indicated by an arrow of each of the first through third directions DR1 through DR3 may be referred to as one side, and the opposite direction may be referred to as the other side. In addition, in the present specification, “on”, “upper side”, “above”, “top”, and “upper surface” refer to a direction in which the arrow of the third direction DR3 points in the drawings, and “under”, “lower side”, “below”, “bottom”, and “lower surface” refer to a direction opposite to the direction in which the arrow of the third direction DR3 points in the drawings.

The display device 10 may include a display area DA displaying an image and a non-display area NDA that does not display an image. In an embodiment, the non-display area NDA may be positioned around the display area DA and may surround the display area DA.

In an embodiment, as illustrated in FIG. 2, the display device 10 may include a display substrate 100 and a color conversion substrate 200 facing the display substrate 100 and may further include a sealing portion 400 bonding the display substrate 100 and the color conversion substrate 200 together and a filler 300 filling a space between the display substrate 100 and the color conversion substrate 200.

The display substrate 100 may include elements and circuits for displaying an image, for example, pixel circuits such as switching elements, a pixel defining layer defining emission areas and a non-emission area, which will be described later, in the display area DA, and self-light emitting elements. In an embodiment, the self-light emitting elements may include at least one of an organic light emitting diode, a quantum dot light emitting diode, an inorganic material-based micro light emitting diode (e.g., micro LED), and an inorganic material-based nano light emitting diode (e.g., nano LED). For ease of description, a case where the self-light emitting elements are organic light emitting diodes will be described below as an example.

The color conversion substrate 200 may be positioned on the display substrate 100 and may face the display substrate 100. In an embodiment, the color conversion substrate 200 may include a color conversion pattern that converts the color of incident light. In an embodiment, the color conversion pattern may include at least any one of a color filter and a wavelength conversion pattern.

The sealing portion 400 may be positioned between the display substrate 100 and the color conversion substrate 200 in the non-display area NDA. The sealing portion 400 may be disposed along edge portions of the display substrate 100 and the color conversion substrate 200 in the non-display area NDA to surround the display area DA in plan view. The display substrate 100 and the color conversion substrate 200 may be bonded to each other by the sealing portion 400.

In an embodiment, the sealing portion 400 may be made of an organic material. For example, the sealing portion 400 may be made of epoxy resin. However, embodiments are not limited thereto.

The filler 300 may be positioned in the space surrounded by the sealing portion 400 between the display substrate 100 and the color conversion substrate 200. The filler 300 may fill the space between the display substrate 100 and the color conversion substrate 200.

In an embodiment, the filler 300 may be made of a material that can transmit light. In an embodiment, the filler 300 may be made of an organic material. For example, the filler 300 may be made of a silicon-based organic material or an epoxy-based organic material. However, embodiments are not limited thereto. In another example, the filler 300 may also be omitted.

In an embodiment, as illustrated in FIG. 3, the display device 10_1 may not include the sealing portion 400. For example, a color conversion substrate 200_1 of the display device 10_1 may be an encapsulation substrate. The color conversion substrate 200_1 may include a protruding portion disposed along the periphery of the color conversion substrate 200_1 and protruding toward a display substrate 100 in the third direction DR3 and a recessed portion surrounded by the protruding portion. The internal space may be sealed by the display substrate 100, the color conversion substrate 200_1, and the protruding portion. A filler 300 may fill the recessed portion.

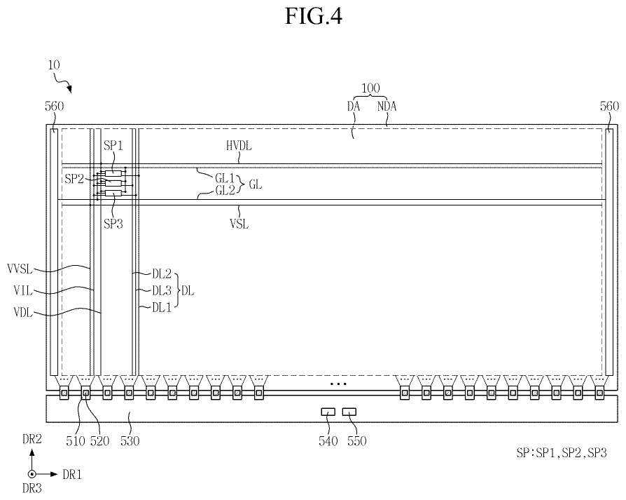

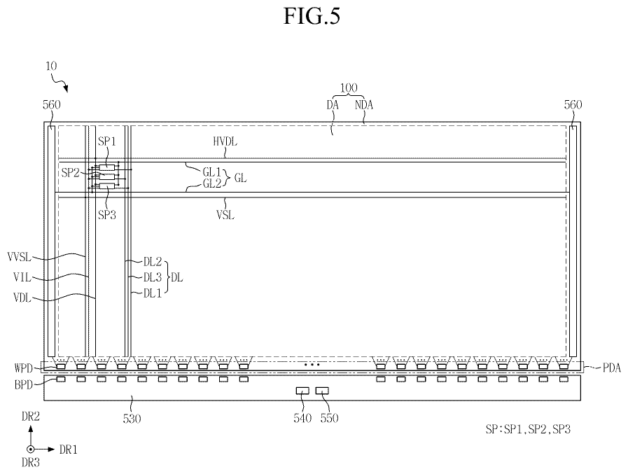

FIG. 4 is a schematic plan view illustrating a state in which connection films 510 are attached to wiring pads WPD of the display device 10 according to the embodiment of FIG. 1. FIG. 5 is a schematic plan view illustrating a state in which the connection films 510 are not attached to the wiring pads WPD of the display device 10 according to the embodiment of FIG. 1.

Referring to FIGS. 4 and 5, the display device 10 may include the display substrate 100, the connection films 510, display drivers 520, a circuit board 530, a timing controller 540, a power supply 550, and gate drivers 560.

The display substrate 100 may be rectangular in plan view. For example, the display substrate 100 may be shaped like a rectangular plane having long sides in the first direction DR1 and short sides in the second direction DR2. Each corner where a long side extending in the first direction DR1 meets a short side extending in the second direction DR2 may be right-angled or may be rounded to have a predetermined (or selected) curvature. The planar shape of the display substrate 100 is not limited to a rectangular shape and may also be other polygonal shapes, a circular shape, or an oval shape. For example, the display substrate 100 may be formed flat, but embodiments are not limited thereto. For another example, the display substrate 100 may be formed to be bent with a predetermined (or selected) curvature.

The display substrate 100 may include a display area DA and a non-display area NDA.

The display area DA may be an area for displaying an image and may be defined as a central area of the display substrate 100. In an embodiment, the display area DA may include pixels SP, gate lines GL, data lines DL, initialization voltage lines VIL, first voltage lines VDL, horizontal voltage lines HVDL, vertical voltage lines VVSL, and second voltage lines VSL.

The pixels SP may be respectively formed in pixel areas intersected by the data lines DL and the gate lines GL. In an embodiment, the pixels SP may include first through third pixels SP1, SP2, and SP3. Each of the first through third pixels SP1, SP2, and SP3 may be connected to a gate line GL and a data line DL. Each of the first through third pixels SP1, SP2, and SP3 may be defined as a smallest unit area that outputs light.

Each of the first through third pixels SP1, SP2, and SP3 may include an organic light emitting diode including an organic light emitting layer, a quantum dot light emitting diode including a quantum dot light emitting layer, a micro light emitting diode, or an inorganic light emitting diode including an inorganic semiconductor.

The first pixels SP1 may emit light of a first color or red light, the second pixels SP2 may emit light of a second color or green light, and the third pixels SP3 may emit light of a third color or blue light. Pixel circuits of the first pixels SP1, pixel circuits of the second pixels SP2, and pixel circuits of the third pixels SP3 may be sequentially arranged in a direction opposite to the second direction DR2, but the order of the pixel circuits is not limited thereto.

The gate lines GL may include first gate lines GL1 and second gate lines GL2. The first gate lines GL1 may extend in the first direction DR1 and may be spaced apart from each other in the second direction DR2. The first gate lines GL1 may receive first gate signals from the gate drivers 560 and supply the first gate signals to the first through third pixels SP1, SP2, and SP3.

The second gate lines GL2 may extend in the first direction DR1 and may be spaced apart from each other in the second direction DR2. The second gate lines GL2 may receive second gate signals from the gate drivers 560 and supply the second gate signals to the first through third pixels SP1, SP2, and SP3.

The data lines DL may extend in the second direction DR2 and may be spaced apart from each other in the first direction DR1. The data lines DL may include first through third data lines DL1 through DL3. The first through third data lines DL1 through DL3 may supply data voltages to the first through third pixels SP1, SP2, and SP3, respectively.

The initialization voltage lines VIL may extend in the second direction DR2 and may be spaced apart from each other in the first direction DR1. The initialization voltage lines VIL may supply initialization voltages VINT received from the display drivers 520 to the pixel circuits of the first through third pixels SP1, SP2, and SP3. The initialization voltage lines VIL may receive sensing signals from the pixel circuits of the first through third pixels SP1, SP2, and SP3 and supply the sensing signals to the display drivers 520.

The first voltage lines VDL may extend in the second direction DR2 and may be spaced apart from each other in the first direction DR1. The first voltage lines VDL may supply driving voltages or high potential voltages received from the power supply 550 to the first through third pixels SP1, SP2, and SP3.

The horizontal voltage lines HVDL may extend in the first direction DR1 and may be spaced apart from each other in the second direction DR2. The horizontal voltage lines HVDL may be connected to the first voltage lines VDL. The horizontal voltage lines HVDL may receive driving voltages or high potential voltages from the first voltage lines VDL.

The vertical voltage lines VVSL may extend in the second direction DR2 and may be spaced apart from each other in the first direction DR1. The vertical voltage lines VVSL may be connected to the second voltage lines VSL. The vertical voltage lines VVSL may supply low potential voltages received from the power supply 550 to the second voltage lines VSL.

The second voltage lines VSL may extend in the first direction DR1 and may be spaced apart from each other in the second direction DR2. The second voltage lines VSL may supply low potential voltages to the first through third pixels SP1, SP2, and SP3.

The connection relationship between the pixels SP, the gate lines GL, the data lines DL, the initialization voltage lines VIL, the first voltage lines VDL, the horizontal voltage lines HVDL, the vertical voltage lines VVSL, and the second voltage lines VSL may be variously designed and changed according to the number and arrangement of the pixels SP.

The non-display area NDA may be defined as an area other than the display area DA in the display substrate 100. For example, the non-display area NDA may include fan-out lines connecting the data lines DL, the initialization voltage lines VIL, the first voltage lines VDL and the vertical voltage lines VVSL to the display drivers 520 and may include the gate drivers 560 and the wiring pads WPD connected to the connection films 510.

The non-display area NDA may include a pad area PDA where the wiring pads WPD are disposed. The pad area PDA may be positioned adjacent to a side of the display device 10. For example, the pad area PDA may be positioned adjacent to a lower side of the display device 10. In an embodiment, the pad area PDA may extend along the first direction DR1.

The connection films 510 may be connected to the wiring pads WPD disposed on a lower side of the non-display area NDA and board pads BPD disposed on an upper side of the circuit board 530. For example, input terminals, e.g., bumps disposed on one side and the other side of the connection films 510 may be attached to the wiring pads WPD and the board pads BPD by a film attaching process. For example, each of the connection films 510 may be bendable like a tape carrier package or a chip on film. The connection films 510 may be bent toward the bottom of the display substrate 100 to reduce a bezel area of the display device 10.

The display drivers 520 may be mounted on the connection films 510. For example, the display drivers 520 may be implemented as integrated circuits (ICs). The display drivers 520 may receive digital video data and a data control signal from the timing controller 540, convert the digital video data into analog data voltages according to the data control signal, and supply the analog data voltages to the data lines DL through the fan out lines.

The circuit board 530 may support the timing controller 540 and the power supply 550 and supply signals and power to the display drivers 520. For example, the circuit board 530 may supply signals supplied from the timing controller 540 and power supply voltages supplied from the power supply 550 to the connection films 510 and the display drivers 520 through the board pads BPD in order to display an image in each pixel. For example, signal lines and power lines may be provided on the circuit board 530.

The timing controller 540 may be mounted on the circuit board 530 and may receive image data and a timing synchronization signal from a display driving system or a graphics device through a user connector provided on the circuit board 530. The timing controller 540 may generate digital video data by arranging the image data according to the pixel arrangement structure based on the timing synchronization signal and supply the generated digital video data to the display drivers 520. The timing controller 540 may generate a data control signal and a gate control signal based on the timing synchronization signal. The timing controller 540 may control the data voltage supply timing of the display drivers 520 based on the data control signal and may control the gate signal supply timing of the gate drivers 560 based on the gate control signal.

The power supply 550 may be disposed on the circuit board 530 to supply a power supply voltage to the connection films 510 and the display drivers 520. For example, the power supply 550 may generate a driving voltage or a high potential voltage and supply the driving voltage or the high potential voltage to the first voltage lines VDL, may generate a low potential voltage and supply the low potential voltage to the vertical voltage lines VVSL, and may generate an initialization voltage VINT and supply the initialization voltage to the initialization voltage lines VIL.

The gate drivers 560 may be disposed on at least any one of left and right sides of the non-display area NDA. The gate drivers 560 may generate gate signals based on a gate control signal supplied from the timing controller 540. The gate control signal may include a start signal, a clock signal, and a power supply voltage. However, embodiments are not limited thereto. The gate drivers 560 may supply the gate signals to the gate lines GL according to a set order.

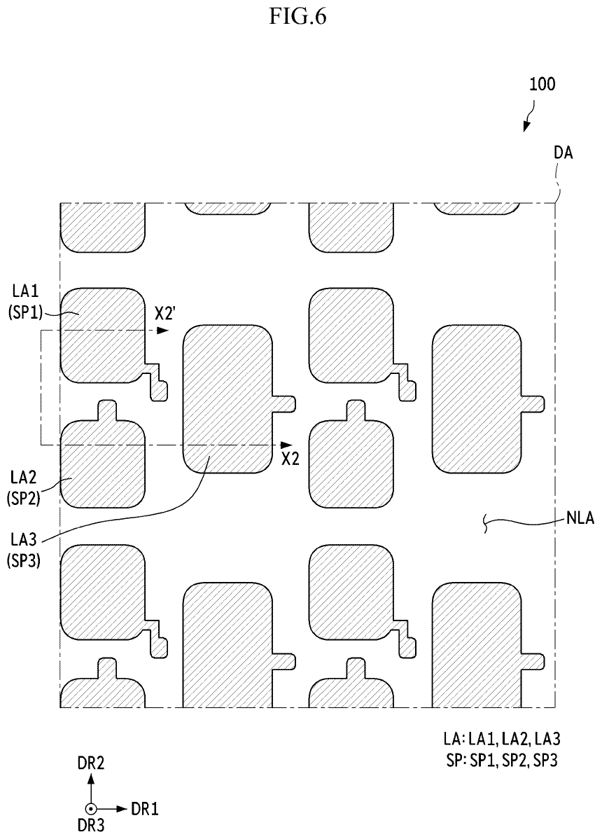

FIG. 6 is a schematic plan view of a part of the display area DA of the display substrate 100 according to an embodiment.

Referring to FIG. 6 in addition to FIGS. 1 through 3, emission areas LA and a non-emission area NLA may be defined in the display area DA of the display substrate 100. The emission areas LA may be areas where light generated by light emitting elements of the display substrate 100 is emitted to the outside of the display substrate 100, and the non-emission area NLA may be an area where light generated by the light emitting elements of the display substrate 100 is not emitted to the outside of the display substrate 100. In some embodiments, the emission areas LA may include first emission areas LA1, second emission areas LA2, and third emission areas LA3.

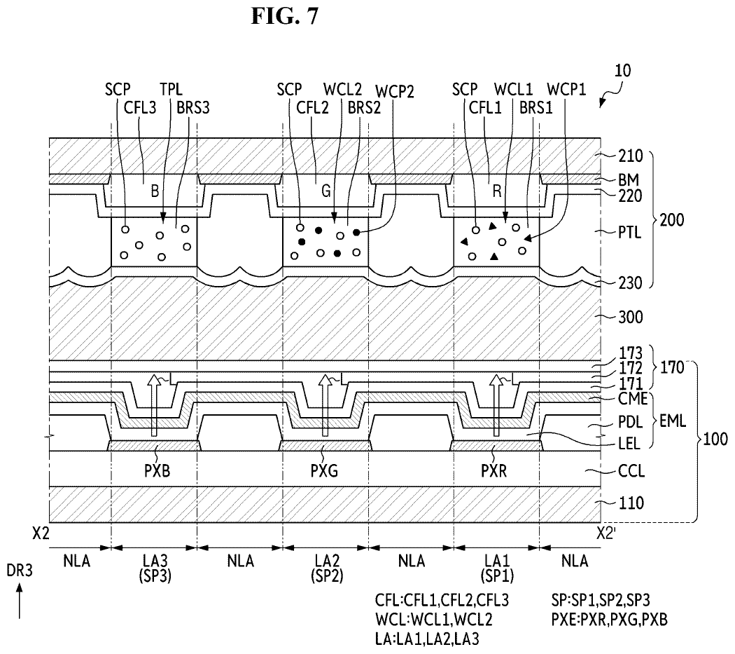

In some embodiments, the emission areas LA and the non-emission area NLA may be defined by a pixel defining layer PDL (see FIG. 7). For example, the emission areas LA may be areas overlapping openings of the pixel defining layer PDL (see FIG. 7), and the non-emission area NLA may be an area that does not overlap the openings of the pixel defining layer PDL (see FIG. 7).

In an embodiment, light emitted from the emission areas LA of the display substrate 100 to the color conversion substrate 200 may be light of the third color. For example, the light of the third color may be blue light and may have a peak wavelength in the range of about 440 nm to about 480 nm. The peak wavelength may refer to a wavelength having maximum intensity in a wavelength region. However, embodiments are not limited thereto, and the light emitted from the emission areas LA of the display substrate 100 to the color conversion substrate 200 may also be light in an ultraviolet region.

In case that the first through third emission areas LA1, LA2, and LA3 emit light of the same color, the first through third pixels SP1, SP2, and SP3 may express various colors through color conversion patterns included in the color conversion substrate 200 (see FIG. 7).

In an embodiment, the first through third emission areas LA1, LA2, and LA3 may emit light of different colors. For example, light emitted from the first emission areas LA1 may be red light, light emitted from the second emission areas LA2 may be green light, and light emitted from the third emission areas LA3 may be blue light.

A first emission area LA1, a second emission area LA2, and a third emission area LA3 may constitute a first pixel SP1, a second pixel SP2, and a third pixel SP3, respectively. The first emission area LA1, the second emission area LA2, and the third emission area LA3 may be repeatedly disposed over the entire display area DA along the first direction DR1 and the second direction DR2. The first emission area LA1, the second emission area LA2, and the third emission area LA3 may constitute a unit color pixel (e.g., single unit color pixel).

In an embodiment, as illustrated in FIG. 6, the first through third emission areas LA1, LA2, and LA3 may have a rectangular planar shape or a rhombus planar shape. However, this is an example, and the planar shape of the emission areas LA according to embodiments is not limited to the shape illustrated in FIG. 7. For example, the emission areas LA may also have a polygonal shape such as a square, a pentagon or a hexagon or have a circular or oval shape including curved edge portions in plan view.

The first emission areas LA1 may be arranged parallel to each other in the first direction DR1.

The second emission areas LA2 may be arranged parallel to each other in the first direction DR1.

Each of the third emission areas LA3 may neighbor a portion of each of the first emission areas LA1 and a portion of each of the second emission areas LA2 in the first direction DR1.

In the second direction DR2, the first emission areas LA1 and the second emission areas LA2 may be arranged alternately and parallel to each other.

In the second direction DR2, the third emission areas LA3 may be arranged parallel to each other.

Among the first emission areas LA1, the second emission areas LA2, and the third emission areas LA3, the third emission areas LA3 may have a largest area, and the first emission areas LA1 may have a smallest area.

For example, the first emission areas LA1, the second emission areas LA2, and the third emission areas LA3 may have the same or similar widths in the first direction DR1. However, among the first emission areas LA1, the second emission areas LA2, and the third emission areas LA3, the third emission areas LA3 may have a largest width in the second direction DR2, and the first emission areas LA1 may have a smallest width in the second direction DR2.

For example, pixels SP may be formed by a first emission area LA1, a second emission area LA2, and a third emission area LA3 adjacent to each other among the emission areas LA that display respective luminance and colors.

For example, the pixels SP may be basic units that display various colors, including white, with a predetermined (or selected) luminance.

Each of the pixels SP may include at least one first emission area LA1, at least one second emission area LA2, and at least one third emission area LA3 adjacent to each other. Accordingly, each of the pixels SP may display various colors through mixing of light emitted from the first emission area LA1, the second emission area LA2, and the third emission area LA3 adjacent to each other.

FIG. 7 is a schematic cross-sectional view taken along line X2-X2′ of FIG. 6.

Referring to FIG. 7 in addition to FIG. 6, the display device 10 may include the display substrate 100, the color conversion substrate 200 facing the display substrate 100, and the filler 300 bonding the display substrate 100 and the color conversion substrate 200 together.

The display substrate 100 may include a first substrate 110, a circuit layer CCL, a light emitting element layer EML, and an encapsulation structure 170.

The first substrate 110 may include a transparent material. For example, the first substrate 110 may include a transparent insulating material such as glass or quartz. The first substrate 110 may be a rigid substrate. However, the first substrate 110 is not limited thereto. The first substrate 110 may also include plastic such as polyimide or may have flexible properties so that it may be curved, bent, folded, or rolled.

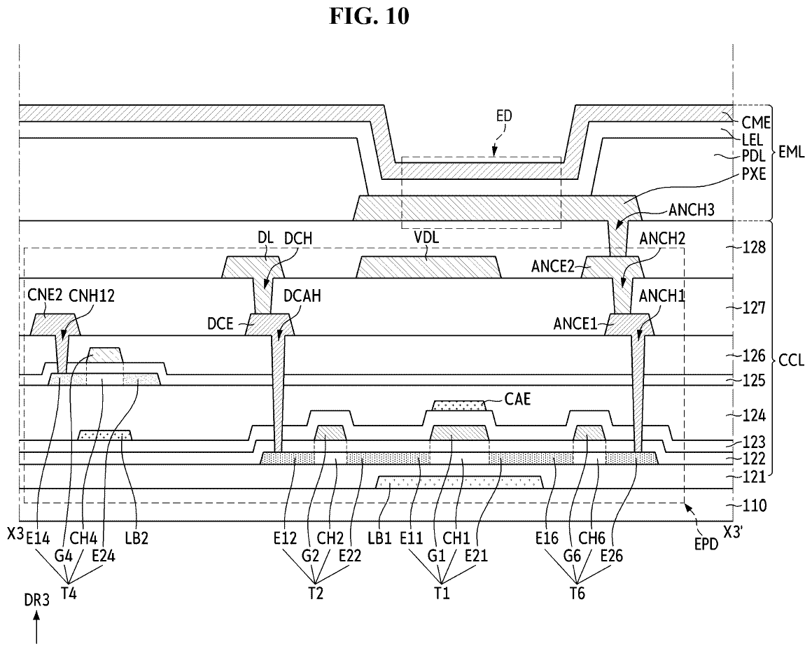

The circuit layer CCL (e.g., thin-film transistor layer) may be disposed on the first substrate 110. The circuit layer CCL will be described later with reference to FIG. 10, etc.

The light emitting element layer EML may be disposed on the circuit layer CCL. The light emitting element layer EML may include pixel electrodes PXE, the pixel defining layer PDL, a light emitting layer LEL, and a common electrode CME.

The pixel electrodes PXE may be first electrodes, e.g., anodes of light emitting diodes. The pixel electrodes PXE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is positioned close to the light emitting layer LEL. The pixel electrodes PXE may have a multilayer structure of ITO/Mg, ITO/MgF, ITO/Ag, or ITO/Ag/ITO. However, embodiments are not limited thereto.

The pixel electrodes PXE may include a first pixel electrode PXR, a second pixel electrode PXG, and a third pixel electrode PXB. The first pixel electrode PXR may overlap a first emission area LA1. The second pixel electrode PXG may overlap a second emission area LA2. The third pixel electrode PXB may overlap a third emission area LA3.

The pixel defining layer PDL may be disposed on a surface of the first substrate 110 along the boundaries of the pixels SP. The pixel defining layer PDL may be disposed on the pixel electrodes PXE and may include openings exposing the pixel electrodes PXE. The emission areas LA and the non-emission area NLA may be defined by the pixel defining layer PDL and its openings.

The pixel defining layer PDL may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB). The pixel defining layer PDL may also include an inorganic material.

The light emitting layer LEL may be disposed on the pixel electrodes PXE exposed by the pixel defining layer PDL. The light emitting layer LEL may contact not only the pixel electrodes PXE, but also side and upper surfaces of the pixel defining layer PDL. The light emitting layer LEL may be connected without distinguishing between the emission areas LA and between the pixels SP. The light emitting layer LEL may be disposed over the entire surface without distinguishing between the emission areas LA and between the pixels SP. Accordingly, the light emitting layer LEL of the emission areas LA1, LA2, and LA3 may emit light having the same wavelength. For example, the light emitting layer LEL of the emission areas LA1, LA2, and LA3 may emit blue light or ultraviolet light, and a wavelength conversion layer WCL included in the color conversion substrate 200 to be described later may enable each pixel SP to display a corresponding color.

In an embodiment, light emitting layers LEL may be respectively disposed in the emission areas LA1, LA2, and LA3 separated by the pixel defining layer PDL. For example, the light emitting layers LEL of the emission areas LA1, LA2, and LA3 may emit light having the same wavelength.

In an embodiment in which the display device 10 is an organic light emitting display device, the light emitting layer LEL may include an organic layer including an organic material. The organic layer may include an organic light emitting layer. In some cases, the organic layer may further include at least one of a hole injection layer, a hole transport layer, an electron transport layer, and an electron injection layer as an auxiliary layer for facilitate light emission. In an embodiment, in case that the display device 10 is a micro-LED display device or a nano-LED display device, the light emitting layer LEL may include an inorganic material such as an inorganic semiconductor.

In some embodiments, the light emitting layer LEL may have a tandem structure including organic light emitting layers overlapping each other in a thickness direction and a charge generation layer disposed between the organic light emitting layers. The organic light emitting layers overlapping each other may emit light of the same wavelength or may emit light of different wavelengths. At least some layers of the light emitting layer LEL of each pixel SP may be separated from those of the light emitting layer LEL of a neighboring pixel SP by the pixel defining layer PDL or may be connected to those of the light emitting layer LEL of the neighboring pixel SP.

The common electrode CME may be disposed on the light emitting layer LEL. The common electrode CME may be connected without distinguishing between the emission areas LA and the pixels SP. The common electrode CME may be a whole-surface electrode disposed over the entire surface without distinguishing between the emission areas LA and between the pixels SP. The common electrode CME may be second electrodes, e.g., cathodes of the light emitting diodes. The common electrode CME may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The common electrode CME may further include a transparent metal oxide layer disposed on the material layer having a small work function.

The pixel electrodes PXE, the light emitting layer LEL, and the common electrode CME may constitute light emitting elements (e.g., organic light emitting diodes). Light emitted from the light emitting layer LEL may be output upward through the common electrode CME.

The encapsulation structure 170 may be disposed on the common electrode CME. The encapsulation structure 170 may include at least one thin-film encapsulation layer. For example, the encapsulation structure 170 may include a first encapsulating inorganic layer 171, an encapsulating organic layer 172, and a second encapsulating inorganic layer 173.

The first encapsulating inorganic layer 171 may be disposed on the light emitting element layer EML. The first encapsulating inorganic layer 171 may include silicon nitride (SiNₓ), silicon oxide (SiOₓ), or silicon oxynitride (SiOₓN_{y}).

The encapsulating organic layer 172 may be disposed on the first encapsulating inorganic layer 171. The encapsulating organic layer 172 may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB).

The second encapsulating inorganic layer 173 may be disposed on the encapsulating organic layer 172. The second encapsulating inorganic layer 173 and the first encapsulating inorganic layer 171 may include the same material as described above. For example, the second encapsulating inorganic layer 173 may include silicon nitride (SiNₓ), silicon oxide (SiOₓ), or silicon oxynitride (SiOₓN_{y}).

In some embodiments, some layers of the encapsulation structure 170 or the entire encapsulation structure 170 may be omitted. In case that the encapsulation structure 170 is omitted, the filler 300, the sealing portion 400, and the color conversion substrate 200 may be disposed (e.g., directly disposed) on the light emitting element layer EML and may perform an encapsulation function.

The color conversion substrate 200 may be disposed on the encapsulation structure 170 to face the display substrate 100. The color conversion substrate 200 may include a second substrate 210, a light blocking member BM, color filter layers CFL, a first capping layer 220, a partition wall PTL, a wavelength conversion layer WCL, a light transmitting layer TPL, and a second capping layer 230.

The second substrate 210 may include a transparent material. The second substrate 210 may include a transparent insulating material such as glass or quartz. The second substrate 210 may be a rigid substrate. However, the second substrate 210 is not limited thereto. The second substrate 210 may also include plastic such as polyimide or may have flexible properties so that it may be curved, bent, folded, or rolled.

The second substrate 210 and the first substrate 110 may be the same substrate. In another example, the second substrate 210 and the first substrate 110 may have different materials, different thicknesses, and different transmittances. For example, the second substrate 210 may have higher transmittance than the first substrate 110. The second substrate 210 may be thicker or thinner than the first substrate 110.

The light blocking member BM may be disposed on a surface of the second substrate 210, which faces the first substrate 110, along the boundaries of the pixels SP. The light blocking member BM may overlap the pixel defining layer PDL of the display substrate 100 and may be positioned in the non-emission area NLA. The light blocking member BM may include openings exposing the surface of the second substrate 210 which overlaps the emission areas LA. The light blocking member BM may be formed in a lattice shape in plan view.

The light blocking member BM may include an organic material. The light blocking member BM may reduce color distortion due to reflection of external light by absorbing the external light. For example, the light blocking member BM may prevent light emitted from the light emitting layer LEL from transmitting into adjacent pixels SP.

In an embodiment, the light blocking member BM may absorb all visible light wavelengths. The light blocking member BM may include a light absorbing material. For example, the light blocking member BM may be made of a material such as a black matrix of the display device 10.

In an embodiment, the light blocking member BM may absorb light of a specific wavelength among the visible light wavelengths and transmit light of another specific wavelength. For example, the light blocking member BM and a color filter layer CFL may include the same material. For example, the light blocking member BM may be made of the same material as a blue color filter layer B. In some embodiments, the light blocking member BM may be integral with the blue color filter layer B. In another example, the light blocking member BM may also be omitted.

The color filter layers CFL may be disposed on the surface of the second substrate 210 on which the light blocking member BM is disposed. The color filter layers CFL may be disposed on the surface of the second substrate 210 exposed through the openings of the light blocking member BM. Further, each of the color filter layers CFL may be disposed on a portion of the adjacent light blocking member BM.

The color filter layers CFL may include a first color filter layer CFL1 disposed in a first pixel SP1, a second color filter layer CFL2 disposed in a second pixel SP2, and a third color filter layer CFL3 disposed in a third pixel SP3. Each color filter layer CFL may include a colorant such as a dye or pigment that absorbs wavelengths other than a corresponding color wavelength. The first color filter layer CFL1 may be a red color filter layer R, the second color filter layer CFL2 may be a green color filter layer G, and the third color filter layer CFL3 may be a blue color filter layer B. Although neighboring color filter layers CFL are spaced apart from each other on the light blocking member BM in the drawing, the neighboring color filter layers CFL may also at least partially overlap each other and may disposed on the light blocking member BM.

The first capping layer 220 may be disposed on the color filter layers CFL. The first capping layer 220 may prevent damage to or contamination of the color filter layers CFL by preventing penetration of impurities such as moisture or air from the outside into the color filter layers CFL. For example, the first capping layer 220 may prevent the colorants of the color filter layers CFL from spreading to other elements.

The first capping layer 220 may contact (e.g., directly contact) surfaces (e.g., lower surfaces in FIG. 7) of the color filter layers CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, or silicon oxynitride.

The partition wall PTL may be disposed on the first capping layer 220. The partition wall PTL may be positioned in the non-emission area NLA. The partition wall PTL may overlap the light blocking member BM. The partition wall PTL may include openings exposing the color filter layers CFL. The partition wall PTL may include a photosensitive organic material. However, embodiments are not limited thereto. The partition wall PTL may further include a light blocking material.

The wavelength conversion layer WCL and/or the light transmitting layer TPL may be disposed in spaces formed (or defined) by the openings of the partition wall PTL. The wavelength conversion layer WCL and the light transmitting layer TPL may be formed by an inkjet process using the partition wall PTL as a bank, but embodiments are not limited thereto.

In an embodiment in which the light emitting layer LEL of each pixel SP emits light of the third color, the wavelength conversion layer WCL may include a first wavelength conversion pattern WCL1 disposed in the first pixel SP1 and a second wavelength conversion pattern WCL2 disposed in the second pixel SP2. The light transmitting layer TPL may be disposed in the third pixel SP3.

The first wavelength conversion pattern WCL1 may include a first base resin BRS1 and first wavelength conversion materials WCP1 disposed in the first base resin BRS1. The second wavelength conversion pattern WCL2 may include a second base resin BRS2 and second wavelength conversion materials WCP2 disposed in the second base resin BRS2. The light transmitting layer TPL may include a third base resin BRS3 and scatterers SCP disposed in the third base resin BRS3.

The first through third base resins BRS1, BRS2, and BRS3 may include a light-transmitting organic material. For example, the first through third base resins BRS1, BRS2, and BRS3 may include epoxy resin, acrylic resin, cardo resin, or imide resin. The first through third base resins BRS1, BRS2, and BRS3 may all be made of the same material, but embodiments are not limited thereto.

The scatterers SCP may be metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO) or tin oxide (SnO₂), and the organic particle material may be, for example, acrylic resin or urethane resin.

The first wavelength conversion materials WCP1 may convert the third color into the first color, and the second wavelength conversion materials WCP2 may convert the third color into the second color. The first wavelength conversion materials WCP1 and the second wavelength conversion materials WCP2 may be quantum dots, quantum rods, or phosphors. The quantum dots may include group IV nanocrystals, group II-VI compound nanocrystals, group III-V compound nanocrystals, group IV-VI nanocrystals, or a combination thereof. The first wavelength conversion pattern WCL1 and the second wavelength conversion pattern WCL2 may further include scatterers SCP to increase wavelength conversion efficiency.

The light transmitting layer TPL disposed in the third pixel SP3 may transmit light of the third color emitted from the light emitting layer LEL while maintaining the wavelength of the light. The scatterers SCP of the light transmitting layer TPL may control an emission path of light emitted through the light transmitting layer TPL. The light transmitting layer TPL may not include a wavelength conversion material.

The second capping layer 230 may be disposed on the wavelength conversion layer WCL, the light transmitting layer TPL, and the partition wall PTL. The second capping layer 230 may be made of an inorganic material. The second capping layer 230 may include a material selected from the materials listed as materials of the first capping layer 220. The second capping layer 230 and the first capping layer 220 may be made of the same material, but embodiments are not limited thereto.

The filler 300 may be disposed between the display substrate 100 and the color conversion substrate 200. The filler 300 may fill the space between the display substrate 100 and the color conversion substrate 200 and may bond and couple the display substrate 100 and the color conversion substrate 200 to each other. The filler 300 may be disposed between the encapsulation structure 170 of the display substrate 100 and the second capping layer 230 of the color conversion substrate 200. The filler 300 may be made of a Si-based organic material or an epoxy-based organic material. However, embodiments are not limited thereto.

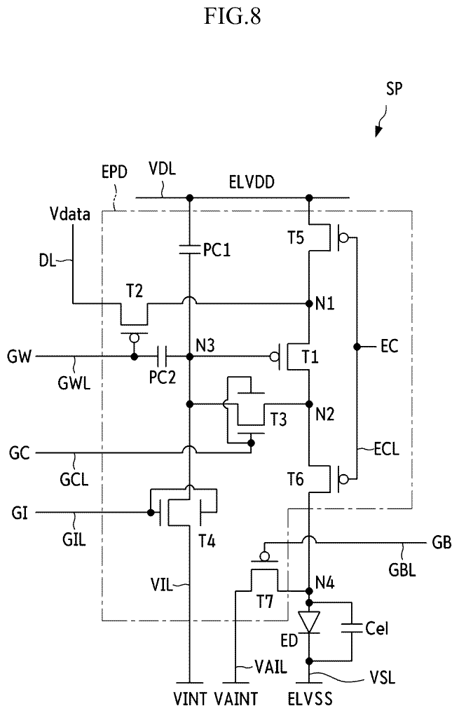

FIG. 8 is a schematic diagram of an equivalent circuit of a pixel SP according to an embodiment.

Referring to FIG. 8, pixels SP may be connected to a scan write line GWL which transmits a scan write signal GW, a scan initialization line GIL which transmits a scan initialization signal GI, an emission control line ECL which transmits an emission control signal EC, a gate control line GCL which transmits a gate control signal GC, and a bias control line GBL which transmits a bias control signal GB.

Each of the pixels SP may include a light emitting pixel driver EPD and a light emitting element ED. In an embodiment, as illustrated in the drawing, the light emitting pixel driver EPD of each pixel SP may include a first transistor T1 which generates a driving current for driving the light emitting element ED, two or more transistors T2, T3, T4, T5, T6, and T7 which are electrically connected to the first transistor T1 or the light emitting element ED, and at least one capacitor PC1.

The first transistor T1 may be electrically connected between a first node N1 and a second node N2. The first node N1 may be electrically connected to a first electrode (e.g., a source electrode) of the first transistor T1. The second node N2 may be electrically connected to a second electrode (e.g., a drain electrode) of the first transistor T1.

A first pixel capacitor PC1 may be electrically connected between a first power line VDL and a third node N3. The third node N3 may be electrically connected to a gate electrode of the first transistor T1. For example, the gate electrode of the first transistor T1 may be electrically connected to the first power line VDL through the first capacitor PC1.

Accordingly, the potential of the gate electrode of the first transistor T1 may be maintained at a voltage charged in the first power line VDL.

A second transistor T2 may be electrically connected between a data line DL and the first node N1.

For example, the second transistor T2 may be electrically connected between the first electrode of the first transistor T1 and the data line DL.

A second pixel capacitor PC2 may be electrically connected between the scan write line GWL and the third node N3. For example, the gate electrode of the first transistor T1 may be electrically connected to the scan write line GWL through the second capacitor PC2.

The second transistor T2 may be turned on by the scan write signal GW of the scan write line GWL. For example, the first electrode of the first transistor T1 may be electrically connected to the data line DL through the second transistor T2.

A third transistor T3 may be electrically connected between the second node N2 and the third node N3. For example, the third transistor T3 may be electrically connected between the gate electrode of the first transistor T1 and the second electrode of the first transistor T1. The third transistor T3 may be turned on by the gate control signal GC of the gate control line GCL.

Through the turned-on third transistor T3, a voltage difference between the second node N2 and the third node N3 may be initialized.

A fourth transistor T4 may be electrically connected between a first initialization voltage line VIL for supplying a first initialization voltage VINT and the third node N3. For example, the fourth transistor T4 may be connected between the gate electrode of the first transistor T1 and the first initialization voltage line VIL. The fourth transistor T4 may be turned on by the scan initialization signal GI of the scan initialization line GIL.

Through the turned-on fourth transistor T4, the potential of the third node N3 may be initialized.

A fifth transistor T5 may be electrically connected between the first node N1 and the first voltage line VDL.

A sixth transistor T6 may be electrically connected between the second node N2 and a fourth node N4. The fourth node N4 may be electrically connected to a pixel electrode PXE of the light emitting element ED.

For example, the fifth transistor T5 may be electrically connected between the first electrode of the first transistor T1 and the first power line VDL.

The sixth transistor T6 may be electrically connected between the second electrode of the first transistor T1 and the pixel electrode PXE of the light emitting element ED.

For example, the first electrode (e.g., the source electrode) of the first transistor T1 may be electrically connected to the first power line VDL through the fifth transistor T5. For example, the second electrode (e.g., the drain electrode) of the first transistor T1 may be electrically connected to the pixel electrode PXE of the light emitting element ED through the sixth transistor T6.

The fifth transistor T5 and the sixth transistor T6 may be turned on by the emission control signal EC of the emission control line ECL.

In case that a data signal Vdata of the data line DL is transmitted to the first electrode of the first transistor T1 through the turned-on second transistor T2, a voltage difference between the gate electrode of the first transistor T1 and the first electrode of the first transistor T1 may be a difference voltage between first power ELVDD and the data signal Vdata.

At this time, in case that the voltage difference, e.g., gate-source voltage difference between the gate electrode of the first transistor T1 and the first electrode of the first transistor T1 becomes greater than a threshold voltage, the first transistor T1 is turned on. Accordingly, a drain-source current of the first transistor T1 which corresponds to the data signal Vdata may be generated.

Next, in case that the fifth transistor T5 and the sixth transistor T6 are turned on, the first transistor T1 may be connected in series to the light emitting element ED between the first power line VDL and a second power line VSL. For example, a capacitor Cel may be connected to the light emitting element ED in parallel and connected between the fourth node N4 and the second power line VSL. Accordingly, the drain-source current of the first transistor T1 which corresponds to the data signal Vdata may be supplied as a driving current of the light emitting element ED.

Therefore, the light emitting element ED may emit light with a luminance corresponding to the data signal Vdata.

A seventh transistor T7 may be electrically connected between the fourth node N4 and a second initialization voltage line VAIL for supplying a second initialization voltage VAINT. For example, the seventh transistor T7 may be electrically connected between the pixel electrode PXE of the light emitting element ED and the second initialization voltage line VAIL. The seventh transistor T7 may be turned on by the bias control signal GB of the bias control line GBL.

Through the turned-on seventh transistor T7, the potential of the fourth node N4 may be initialized.

According to embodiments, among the first through seventh transistors T1, T2, T3, T4, T5, T6, and T7, the third transistor T3 and the fourth transistor T4 may be N-type metal-oxide-semiconductor field-effect transistors (MOSFETs), and the other transistors T1, T2 and T5 through T7 excluding the third transistor T3 and the fourth transistor T4 may be P-type MOSFETs.

For example, among the first through seventh transistors T1, T2, T3, T4, T5, T6, and T7 included in the light emitting pixel driver EPD, the third transistor T3 and the fourth transistor T4 may be provided as N-type MOSFETs, but the other transistors T1, T2 and T5 through T7 excluding the third and fourth transistors T3 and T4 may be provided as P-type MOSFETs.

Accordingly, according to embodiments, the circuit layer CCL may include a first semiconductor layer (e.g., CH1, E11, E21, CH2, E12, E22, CH6, E16 and E26 of FIG. 10) and a second semiconductor layer (e.g., CH4, E14 and E24 of FIG. 10).

The first semiconductor layer may include a channel portion, a first electrode portion and a second electrode portion of each of the P-type MOSFETs that is, the first transistor T1, the second transistor T2, the fifth transistor T5, the sixth transistor T6 and the seventh transistor T7 among the first through seventh transistors T1, T2, T3, T4, T5, T6, and T7 of each light emitting pixel driver EPD. In each of the first transistor T1, the second transistor T2, the fifth transistor T5, the sixth transistor T6 and the seventh transistor T7, the channel portion thereof may overlap a gate electrode thereof. For example, in each of the first transistor T1, the second transistor T2, the fifth transistor T5, the sixth transistor T6 and the seventh transistor T7, the first electrode portion and the second electrode portion thereof may be connected to end portions (e.g., opposite end portions) of the channel portion thereof. The first electrode portion may be a first electrode of a transistor, and the second electrode portion may be a second electrode of the transistor.

The second semiconductor layer may include a channel portion, a first electrode portion and a second electrode portion of each of the N-type MOSFETs (e.g., the third transistor T3 and the fourth transistor T4 among the first through seventh transistors T1, T2, T3, T4, T5, T6, and T7 of each light emitting pixel driver EPD). In each of the third transistor T3 and the fourth transistor T4, the channel portion thereof may be disposed between a first gate electrode and a second gate electrode overlapping each other and may overlap the first gate electrode and the second gate electrode thereof. In each of the third transistor T3 and the fourth transistor T4, the first electrode portion and the second electrode portion thereof may be connected to end portions (e.g., opposite end portions) of the channel portion. The first electrode portion thereof may be a first electrode, and the second electrode portion thereof may be a second electrode.

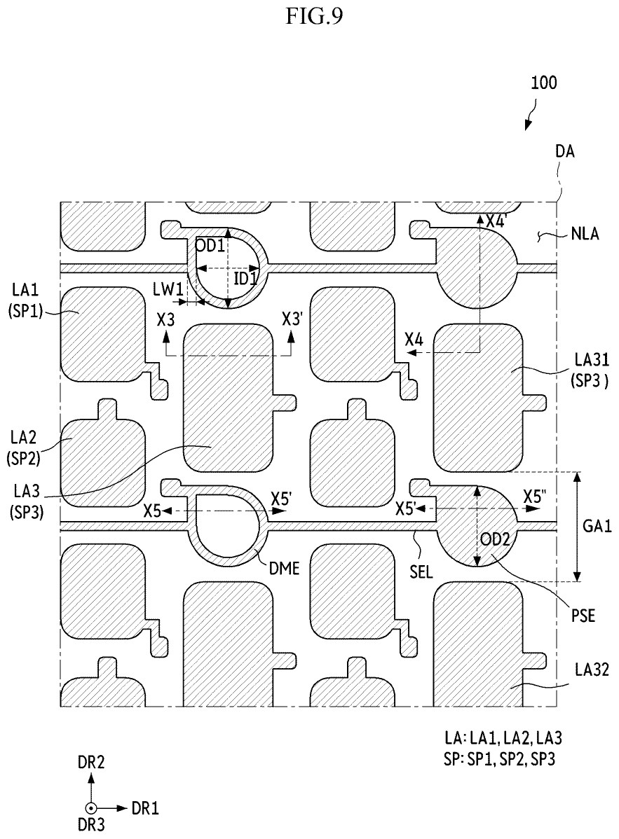

FIG. 9 is a layout view illustrating auxiliary electrodes PSE and dummy electrodes DME of the display area DA of FIG. 6 according to embodiments.

Referring to FIG. 9, a display substrate 100 according to embodiments may include the auxiliary electrodes PSE and the dummy electrodes DME disposed in a part of a non-emission area NLA between emission areas LA.

A first gap area GA1 of a first width may be disposed between two or more third emission areas LA31 and LA32 parallel to each other in the second direction DR2 among third emission areas LA3.

For example, the non-emission area NLA may include the first gap area GA1 disposed with the first width between two or more third emission areas LA31 and LA32 parallel to each other in the second direction DR2.

The auxiliary electrodes PSE or the dummy electrodes DME may be disposed in the first gap area GA1. The auxiliary electrodes PSE may be disposed parallel to each other in the second direction DR2. For example, the dummy electrodes DME may be disposed parallel to each other in the second direction DR2. The dummy electrodes DME and the auxiliary electrodes PSE may be disposed alternately in the first direction DR1.

A ratio of the number of dummy electrodes DME to the number of auxiliary electrodes PSE in the entire display area DA may be about 1:1. However, embodiments are not limited thereto. For example, the ratio of the number of dummy electrodes DME to the number of auxiliary electrodes PSE may be about 1:2 or about 2:1.

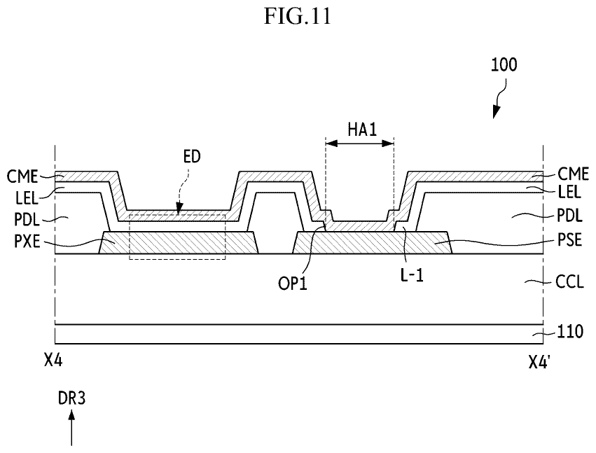

The dummy electrodes DME and the auxiliary electrodes PSE may be disposed in the shape of a line extending in a direction in plan view. For example, the dummy electrodes DME and the auxiliary electrodes PSE may be connected by an auxiliary line SEL extending along the first direction DR1. However, embodiments are not limited thereto, and the dummy electrodes DME and the auxiliary electrodes PSE may also be disposed in the island shape spaced apart from each other in plan view. For example, each of the dummy electrodes DME and the auxiliary electrodes PSE may be disposed in the island shape spaced apart from pixel electrodes PXE (see FIG. 11).

The auxiliary line SEL may be electrically connected to a power line to which a second voltage ELVSS is provided and thus may provide the second voltage (e.g., low potential voltage). For example, the auxiliary electrodes PSE or the dummy electrodes DME may receive the second voltage through the auxiliary line SEL.

The pixel electrodes PXE and at least one of the auxiliary line SEL, the auxiliary electrodes PSE, and the dummy electrodes DME may be disposed on the same layer (e.g., circuit layer CCL).

As described above, the auxiliary electrodes PSE may have a circular shape in plan view or may have a polygonal shape such as a quadrangular shape.

The overall shape of the dummy electrodes DME may be similar to the shape of the auxiliary electrodes PSE, but may be a ring shape (or loop shape) having a first line width LW1. For example, the auxiliary electrodes PSE may be circular, and the dummy electrodes DME may be circular overall, have inner and outer circumferences and may have a uniform first line width LW1 in plan view. In another example, the auxiliary electrodes PSE may be quadrangular, and the dummy electrodes DME may be overall quadrangular ring-shaped in plan view and may have a uniform first line width LW1 in plan view. The first line width LW1 may be about 6 μm to about 12 μm.

A difference between an outer diameter OD1 and an inner diameter ID1 of each dummy electrode DME may be a line width. The outer diameter OD1 of each dummy electrode DME may be substantially equal to an outer diameter OD2 of each auxiliary electrode PSE.

In case that the first line width LW1 is about 6 μm or less, an area where each dummy electrode DME is disposed may be more likely to be visible. In case that the first line width LW1 is about 12 μm or more, a pixel failure may be more likely to occur.

The dummy electrodes DME, the auxiliary electrodes PSE, and the pixel electrodes PXE may be made of the same material. For example, the dummy electrodes DME, the auxiliary electrodes PSE, and the pixel electrodes PXE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is positioned close to a light emitting layer LEL. The pixel electrodes PXE may have a multilayer structure of ITO/Mg, ITO/MgF, ITO/Ag, or ITO/Ag/ITO. However, embodiments are not limited thereto.

FIG. 10 is a schematic cross-sectional view taken along line X3-X3′ of FIG. 9 according to an embodiment.

Referring to FIG. 10 in addition to FIG. 9, the display substrate 100 according to an embodiments may include a first substrate 110, a circuit layer CCL, and a light emitting element layer EML.

Since the first substrate 110 has been described above with reference to FIG. 7, a description thereof will be omitted.

According to embodiments, the circuit layer CCL may be disposed on the first substrate 110. The circuit layer CCL may include an interlayer insulating layer 126 disposed on the substrate 110, a first source-drain conductive layer (e.g., ANCE1, VIL and DCE) disposed on the interlayer insulating layer 126, a first planarization layer 127 covering the first source-drain conductive layer, a second source-drain conductive layer (e.g., DL and ANCE2) disposed on the first planarization layer 127, and a second planarization layer 128 covering the second source-drain conductive layer.

According to embodiments, the circuit layer CCL may further include a first semiconductor layer (e.g., CH1, E11, E21, CH2, E12, E22, CH6, E16 and E26) disposed on the substrate 110, a first gate insulating layer 122 covering the first semiconductor layer, a first gate conductive layer (e.g., G1, G2 and G6) disposed on the first gate insulating layer 122, a second gate insulating layer 123 covering the first gate conductive layer, a second gate conductive layer (e.g., CAE and LB2) disposed on the second gate insulating layer 123, an additional interlayer insulating layer 124 covering the second gate conductive layer, a second semiconductor layer (e.g., CH4, E14 and E24) disposed on the additional interlayer insulating layer 124, a third gate insulating layer 125 covering the second semiconductor layer, and a third gate conductive layer G4 disposed on the third gate insulating layer 125. For example, the interlayer insulating layer 126 may cover the third gate conductive layer G4 on the third gate insulating layer 125.

According to embodiments, the circuit layer CCL may further include a buffer layer 121 covering the substrate 110. For example, the first semiconductor layer may be disposed on the buffer layer 121. The buffer layer 121 may cover a first light blocking portion LB1 on the substrate 110.

The first light blocking portion LB1 may overlap a channel portion CH1 of a first transistor T1.

As described above with reference to FIG. 8, the circuit layer CCL may include light emitting pixel drivers EPD which are respectively electrically connected to light emitting elements ED disposed in the emission areas LA and lines which transmit various signals and voltages to the light emitting pixel drivers EPD.

Each of the light emitting pixel drivers EPD may include the first transistor T1 and two or more transistors T2 through T7 electrically connected to the first transistor T1 or a light emitting element ED.

As illustrated in FIG. 10, according to embodiments, the first transistor T1 may include the channel portion CH1, a first electrode portion E11 and a second electrode portion E21 disposed in the first semiconductor layer on the substrate 110 and a gate electrode G1 disposed in the first gate conductive layer on the first gate insulating layer 122.

The first electrode portion E11 may be connected to a side of the channel portion CH1, and the second electrode portion E21 may be connected to the other side of the channel portion CH1.

The first electrode portion E11 and the second electrode portion E21 may be doped at a higher concentration than the channel portion CH1.

The gate electrode G1 may overlap the channel portion CH1.

For example, a second transistor T2 may include a channel portion CH2, a first electrode portion E12 and a second electrode portion E22 disposed in the first semiconductor layer on the substrate 110 and a gate electrode G2 disposed in the first gate conductive layer on the first gate insulating layer 122 and overlapping the channel portion CH2.

For example, a sixth transistor T6 may include a channel portion CH6, a first electrode portion E16 and a second electrode portion E26 disposed in the first semiconductor layer on the substrate 110 and a gate electrode G6 disposed in the first gate conductive layer on the first gate insulating layer 122 and overlapping the channel portion CH6.

The first electrode portion E12 of the second transistor T2 may be electrically connected to a data line DL through a data connection electrode DCE.

The data connection electrode DCE may be disposed in the first source-drain conductive layer on the interlayer insulating layer 126 and may be electrically connected to the first electrode portion E12 of the second transistor T2 through a data auxiliary connection hole DCAH. The data auxiliary connection hole DCAH may penetrate the interlayer insulating layer 126, the third gate insulating layer 125, the additional interlayer insulating layer 124, the second gate insulating layer 123, and the first gate insulating layer 122.

The data line DL may be disposed in the second source-drain conductive layer on the first planarization layer 127 and may be electrically connected to the data connection electrode DCE through a data connection hole DCH penetrating the first planarization layer 127.

The second electrode portion E22 of the second transistor T2 may be connected to the first electrode portion E11 of the first transistor T1.

The second electrode portion E21 of the first transistor T1 may be connected to the first electrode portion E16 of the sixth transistor T6.

The second electrode portion E26 of the sixth transistor T6 may be electrically connected to a pixel electrode PXE through a first anode connection electrode ANCE1 and a second anode connection electrode ANCE2.

The first anode connection electrode ANCE1 may be disposed in the first source-drain conductive layer on the interlayer insulating layer 126 and may be electrically connected to the second electrode portion E26 of the sixth transistor T6 through a first anode contact hole ANCH1.

The first anode contact hole ANCH1 may penetrate the interlayer insulating layer 126, the third gate insulating layer 125, the additional interlayer insulating layer 124, the second gate insulating layer 123, and the first gate insulating layer 122.

The second anode connection electrode ANCE2 may be disposed in the second source-drain conductive layer on the first planarization layer 127 and may be electrically connected to the first anode connection electrode ANCE1 through a second anode contact hole ANCH2 penetrating the first planarization layer 127.

The pixel electrode PXE may be disposed on the second planarization layer 128 and may be electrically connected to the second anode connection electrode ANCE2 through a third anode contact hole ANCH3 penetrating the second planarization layer 128.

According to embodiments, a fifth transistor T5 (see FIG. 8) and a seventh transistor T7 (see FIG. 8) have substantially the same structure as the first transistor T1, the second transistor T2 and the sixth transistor T6. Therefore, a redundant description of the fifth transistor T5 and the seventh transistor T7 will be omitted below.

The first gate conductive layer on the first gate insulating layer 122 may include gate electrodes of the first transistor T1, the second transistor T2, the fifth transistor T5, the sixth transistor T6, and the seventh transistor T7.

The first gate conductive layer on the first gate insulating layer 122 may further include a scan write line GWL electrically connected to the gate electrode G2 of the second transistor T2 and a bias control line GBL electrically connected to the gate electrode of the seventh transistor T7.

For example, the first gate conductive layer may further include a scan initialization line GIL extending in the first direction DR1.

For example, the first gate conductive layer may further include an emission control line ECL electrically connected to the gate electrode of the fifth transistor T5 and the gate electrode of the sixth transistor T6.

According to embodiments, the circuit layer CCL may further include a capacitor electrode CAE overlapping the gate electrode G1 of the first transistor T1.

The capacitor electrode CAE may be disposed in the second gate conductive layer on the second gate insulating layer 123.

The capacitor electrode CAE may be electrically connected to a first power line VDL (see FIG. 8). For example, the first power line VDL may be disposed in the second gate conductive layer on the second gate insulating layer 123, and the capacitor electrode CAE may be provided as a part of the first power line VDL.

A first pixel capacitor PC1 may be provided between the gate electrode G1 of the first transistor T1 and the first power line VDL (see FIG. 8) by an overlap area between the gate electrode G1 of the first transistor T1 and the capacitor electrode CAE.

According to embodiments, while the first transistor T1, the second transistor T2, and the sixth transistor T6 are P-type MOSFETs, a fourth transistor T4 may be an N-type MOSFET.

Accordingly, the fourth transistor T4 may include a channel portion CH4, a first electrode portion E14 and a second electrode portion E24 disposed in the second semiconductor layer on the additional interlayer insulating layer 124 and a gate electrode G4 disposed in the third gate conductive layer on the third gate insulating layer 125 and overlapping the channel portion CH4.

The fourth transistor T4 may further include a second light blocking portion LB2, which is disposed below the channel portion CH4 and overlaps the channel portion CH4.

The second light blocking portion LB2 may be a bottom gate electrode electrically connected to the gate electrode G4.

For example, the second light blocking portion LB2 may be a part of the scan initialization line GIL.

The scan initialization line GIL may be disposed in the second gate conductive layer on the second gate insulating layer 123.

According to embodiments, a third transistor T3 and the fourth transistor T4 may have substantially the same structure. Therefore, a redundant description of the third transistor T3 will be omitted below.

The first electrode portion E14 of the fourth transistor T4 may be electrically connected to the first initialization voltage line VIL (see FIG. 8) through a second connection electrode CNE2.

The second connection electrode CNE2 may be disposed in the first source-drain conductive layer on the interlayer insulating layer 126.

The second connection electrode CNE2 may be electrically connected to the first electrode portion E14 of the fourth transistor T4 of the second semiconductor layer on the additional interlayer insulating layer 124 through a second connection hole CNH12.

The light emitting element layer EML may be disposed on the circuit layer CCL and may include light emitting elements ED corresponding to the emission areas LA, respectively.

Each of the light emitting elements ED may include a pixel electrode PXE and a common electrode CME facing each other and a light emitting layer LEL disposed between the pixel electrode PXE and the common electrode CME. For example, each of the light emitting elements ED may further include a first common layer disposed between the pixel electrode PXE and the light emitting layer LEL and a second common layer disposed between the light emitting layer LEL and the common electrode CME.

For example, the light emitting element layer EML may include the pixel electrodes PXE disposed in the emission areas LA, a pixel defining layer PDL, which is disposed in the non-emission area NLA between the emission areas LA and covers edge portions of the pixel electrodes PXE, the light emitting layer LEL disposed on the pixel electrodes PXE, and the common electrode CME disposed on the light emitting layer LEL.

A pixel electrode PXE may be disposed in each of the emission areas LA and may be electrically connected to a light emitting pixel driver EPD of the circuit layer CCL.

The pixel electrode PXE may be electrically connected to the second anode connection electrode ANCE2 through the third anode contact hole ANCH3 penetrating the second planarization layer 128.

The first common layer may include an organic material having a hole transporting property or a hole injecting property.

The light emitting layer LEL may include an organic light emitting material which converts electron-hole pairs into light.

The second common layer 136 may include an organic material having an electron transporting property or an electron injecting property.

The common electrode CME may be disposed over the entire display area DA including the emission areas LA. A second power may be commonly applied to the common electrode CME. The common electrode CME may be referred to as a common electrode.

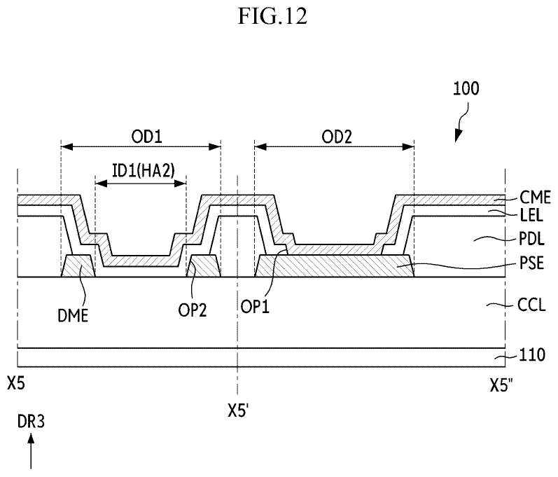

FIG. 11 is a schematic cross-sectional view taken along line X4-X4′ of FIG. 9 according to an embodiment. FIG. 12 is a schematic cross-sectional view taken along lines X5-X5′ and X5′-X5″ of FIG. 9 according to an embodiment.

Referring to FIGS. 11 and 12, a pixel electrode PXE, an auxiliary electrode PSE, and a dummy electrode DME may be disposed on the same layer. For example, the pixel electrode PXE, the auxiliary electrode PSE, and the dummy electrode DME may be disposed on the circuit layer CCL. The description given above with reference to FIG. 10 may apply to the circuit layer CCL.

The pixel electrode PXE may be disposed in a first area on the circuit layer CCL. A portion L-1 of the light emitting layer LEL may overlap the auxiliary electrode PSE in plan view. The pixel defining layer PDL may have an opening OP1 defined (or formed) to expose a portion of the auxiliary electrode PSE. The portion L-1 of the light emitting layer LEL may be disposed within the opening OP1 overlapping the auxiliary electrode PSE. Therefore, the portion L-1 of the light emitting layer LEL may be disposed between the auxiliary electrode PSE and the common electrode CME. A portion of the auxiliary electrode PSE exposed by the portion L-1 of the light emitting layer LEL may be defined as a first opening area HA1. The common electrode CME may be electrically connected to the auxiliary electrode PSE through the first opening area HA1.

The common electrode CME may be provided as an electrode having relatively high light transmittance, so that light generated from the light emitting layer LEL may pass through the common electrode CME and travel toward a display surface. For example, the common electrode CME may be provided as a transparent electrode or as an electrode having a small thickness. For example, the resistance of the common electrode CME may increase, causing a voltage drop (e.g., IR-drop) phenomenon. However, since the common electrode CME contacts the auxiliary electrode PSE, the resistance of the common electrode CME may be reduced, and the voltage drop phenomenon may be prevented.

The dummy electrode DME may have a ring shape (or loop shape) in plan view and may have the inner diameter ID1 and the outer diameter OD1. The outer diameter OD1 of the dummy electrode DME may be substantially equal to the diameter OD2 of the auxiliary electrode PSE. The inner diameter ID1 of the dummy electrode DME may define a second opening area HA2. For example, the dummy electrode DME may include an opening OP2 exposing the circuit layer CCL. (see, e.g., FIG. 12) The circuit layer CCL may be exposed by the second opening area HA2.

The light emitting layer LEL may be disposed on the dummy electrode DME. The light emitting layer LEL may be disposed on the circuit layer CCL exposed by the second opening area HA2. The common electrode CME may be disposed on the light emitting layer LEL. Therefore, the circuit layer CCL, the light emitting layer LEL, and the common electrode CME may sequentially overlap in the second opening area HA2. For example, the dummy electrode DME may not directly contact the common electrode CME. Therefore, the dummy electrode DME may not affect a reduction in the voltage drop (e.g., IR-drop) phenomenon of the common electrode CME.

Since the dummy electrode DME has a smaller area than the auxiliary electrode PSE, its overlap area with the common electrode CME may be reduced. For example, the overlap area between the dummy electrode DME and the common electrode CME may be smaller than an overlap area between the auxiliary electrode PSE and the common electrode CME. Accordingly, random pixel failures may be reduced. A random pixel failure refers to a phenomenon in which a certain pixel of a screen unexpectedly breaks down or operates abnormally.

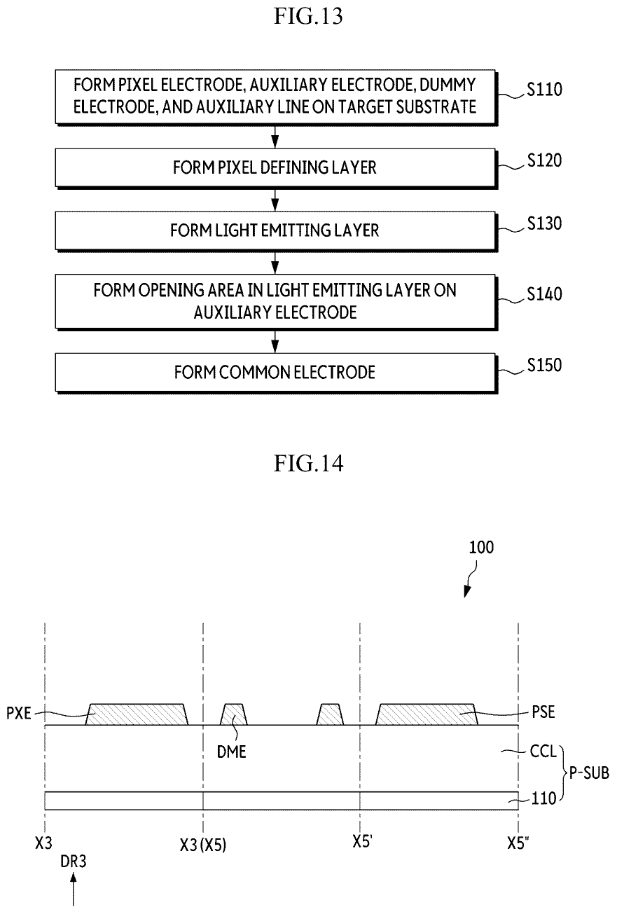

FIG. 13 is a flowchart illustrating a method of manufacturing a display device according to an embodiment. FIGS. 14 through 18 are schematic cross-sectional views of a display substrate 100 for explaining the method of manufacturing the display device according to an embodiment. The cross-sectional views of the display substrate 100 illustrated in FIGS. 14 through 18 correspond to X3-3′, X5-X5′, and X5′-X5″ of FIG. 9.

Referring to FIG. 14, in the method of manufacturing the display device according to an embodiment, a pixel electrode PXE, an auxiliary electrode PSE, a dummy electrode DME, and an auxiliary line SEL may be formed on a target substrate P-SUB (operation S110 of FIG. 13).

The target substrate P-SUB may include a circuit substrate 110 and a circuit layer CCL formed on the circuit substrate 110.

Since the circuit substrate 110 and the circuit layer CCL may be the same as the circuit substrate 110 and the circuit layer CCL described above with reference to FIG. 10, a redundant description thereof will not be repeated. The target substrate P-SUB may correspond to a substrate before the pixel electrode PXE, the auxiliary electrode PSE, the dummy electrode DME, and the auxiliary line SEL are formed.

A conductive material may be deposited and formed on the circuit layer CCL on the entire surface of the substrate 110. Then, the conductive material may be selectively patterned using a photolithography method. Through this process, the pixel electrode PXE, the auxiliary electrode PSE, the dummy electrode DME, and the auxiliary line SEL (see FIG. 9) may be formed on the circuit layer CCL. Therefore, there is unnecessary to increase the number of processes to form the auxiliary electrode PSE, the dummy electrode DME, and the auxiliary line SEL. Accordingly, the pixel electrode PXE, the auxiliary electrode PSE, the dummy electrode DME, and the auxiliary line SEL may include the same material.

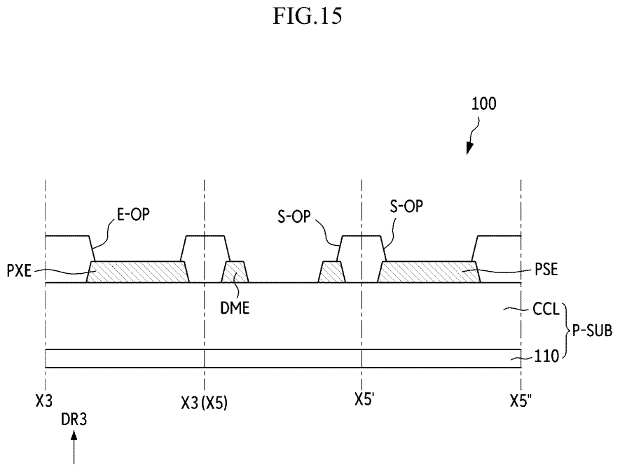

Referring to FIG. 15, a pixel defining layer PDL may be formed between the pixel electrode PXE, the auxiliary electrode PSE, and the dummy electrode DME (operation S120 of FIG. 13).

The pixel defining layer PDL may be formed on the pixel electrode PXE, the auxiliary electrode PSE and the dummy electrode DME by a coating process or a deposition process, and then an emission opening E-OP exposing a portion of the pixel electrode PXE and an opening S-OP exposing a portion of each of the auxiliary electrode PSE and the dummy electrode DME may be formed through a mask process. The pixel defining layer PDL may have a predetermined (or selected) thickness to provide a predetermined (or selected) gap between edge portions of the pixel electrode PXE and a common electrode CME. Accordingly, it is possible to prevent an electric field from being concentrated on the edge portions of the pixel electrode PXE, thereby preventing a short circuit between the pixel electrode PXE and the common electrode CME.

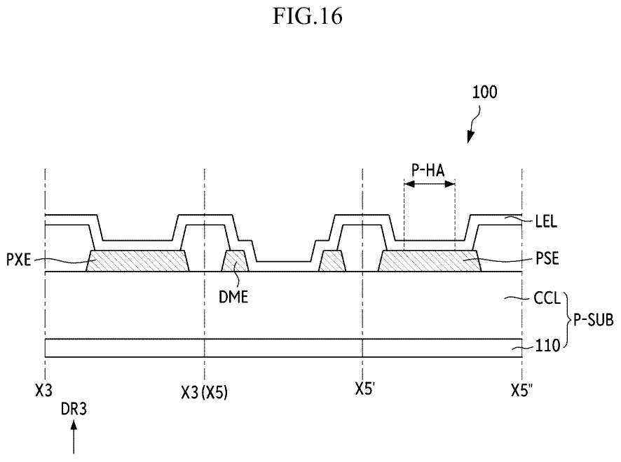

Referring to FIG. 16, a light emitting layer LEL is formed (operation S130 of FIG. 13).

The light emitting layer LEL may be formed on the target substrate P-SUB. The above description of the light emitting layer LEL may apply to the light emitting layer LEL, and a process of forming the light emitting layer LEL will be described below.

The light emitting layer LEL may be formed commonly in an emission area LA and a non-emission area NLA. The light emitting layer LEL may be formed as a common layer using an open mask. However, embodiments are not limited thereto, and the light emitting layer LEL may also be formed in the form of a light emitting pattern disposed to correspond to the pixel electrode PXE.

A portion of the light emitting layer LEL commonly formed in the emission area LA and the non-emission area NLA may be formed on the auxiliary electrode PSE. A preliminary hole area P-HA, in which an opening penetrating the light emitting layer LEL is to be formed, may be defined in the light emitting layer LEL overlapping the auxiliary electrode PSE.

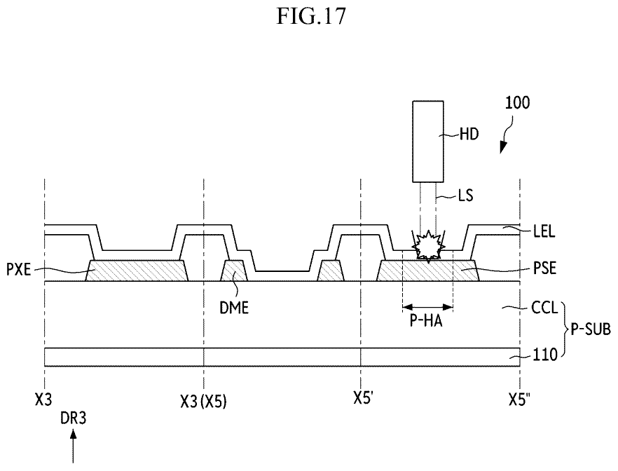

Referring to FIG. 17, an opening area may be formed in a portion of the light emitting layer LEL on the auxiliary electrode PSE through laser drilling (operation S140 of FIG. 13).

For example, a laser generator HD may be provided above the light emitting layer LEL to correspond to the preliminary hole area P-HA. The laser generator HD may irradiate a laser beam LS toward the preliminary hole area P-HA of the light emitting layer LEL. The light emitting layer LEL in the area irradiated with the laser beam LS may be removed by the energy of the laser beam LS. In an embodiment, a wavelength of the laser beam LS may be about 300 nm to about 400 nm. In an embodiment, an output energy of the laser beam LS per unit area may be about 200 mJ/cm².

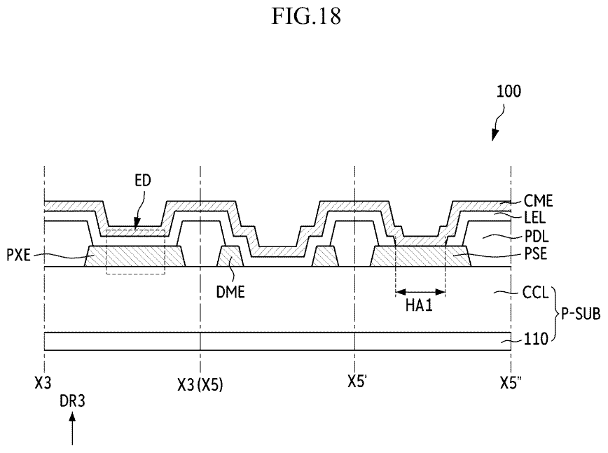

An opening OP1 (see FIG. 18) exposing a portion of the auxiliary electrode PSE may be formed by the laser drilling process.

A first opening area HA1 may correspond to an area of the auxiliary electrode PSE. The first opening area HA1 may have a circular shape in plan view, like a phase of the laser beam LS. A diameter of the first opening area HA1 may be substantially equal to or smaller than a size of the laser beam LS. Therefore, a size of the first opening area HA1 (see FIG. 18) may be variously controlled by controlling the size of the laser beam LS.

Referring to FIG. 18, the common electrode CME may be formed (operation S150 of FIG. 13).

The common electrode CME may be formed on the light emitting layer LEL to face the pixel electrode PXE and may be formed through a deposition process on the first opening area HA1 on the auxiliary electrode PSE to contact a portion of the auxiliary electrode PSE. The auxiliary electrode PSE and the common electrode CME may be connected to each other through the opening OP1.

The method of manufacturing the display device according to an embodiment may further include forming an encapsulation structure 170 (see FIG. 7), a filler 300, and a color conversion substrate 200 on the common electrode CME after forming the common electrode CME according to the configuration of the display substrate 100. However, embodiments are not limited thereto.

Hereinafter, other embodiments of the display device according to an embodiment will be described. In the following embodiments, the same elements as those of the above-described embodiment are identified by the same reference characters, and any redundant description thereof will be omitted or given briefly, and differences will be described.

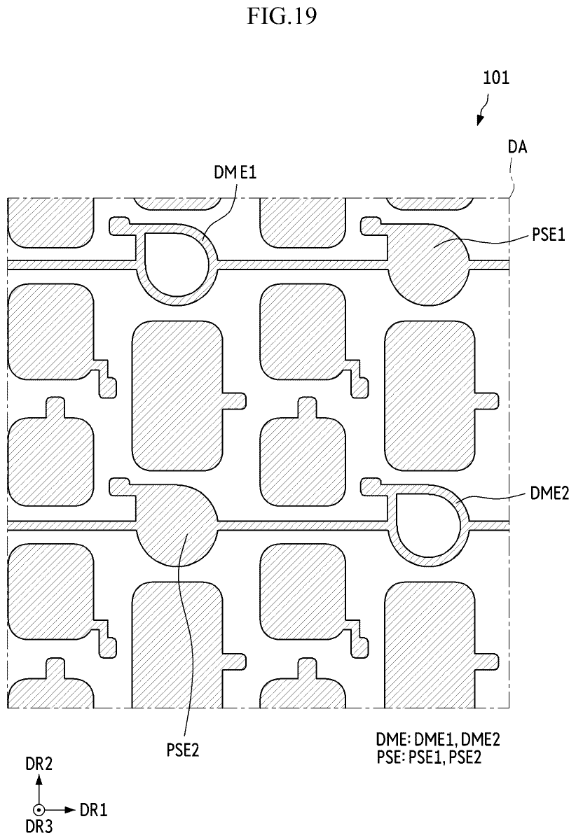

FIG. 19 is a layout view illustrating auxiliary electrodes PSE and dummy electrodes DME of the display area DA of FIG. 6 according to an embodiment.

Referring to FIG. 19, a display panel 101 may include the auxiliary electrodes PSE and dummy electrodes DME.

The auxiliary electrodes PSE and the dummy electrodes DME may be alternately disposed in the first direction DR1 and alternately disposed in the second direction DR1.

For example, a first dummy electrode DME1 may be disposed in a first row and a first column, a first auxiliary electrode PSE1 may be disposed in the first row and a second column, a second auxiliary electrode PSE2 may be disposed in a second row and the first column, and a second dummy electrode DME2 may be disposed in the second row and the second column.

For example, the dummy electrodes DME and the auxiliary electrodes PSE may be arranged regularly throughout the display panel 101, but the arrangement rules may be freely set.

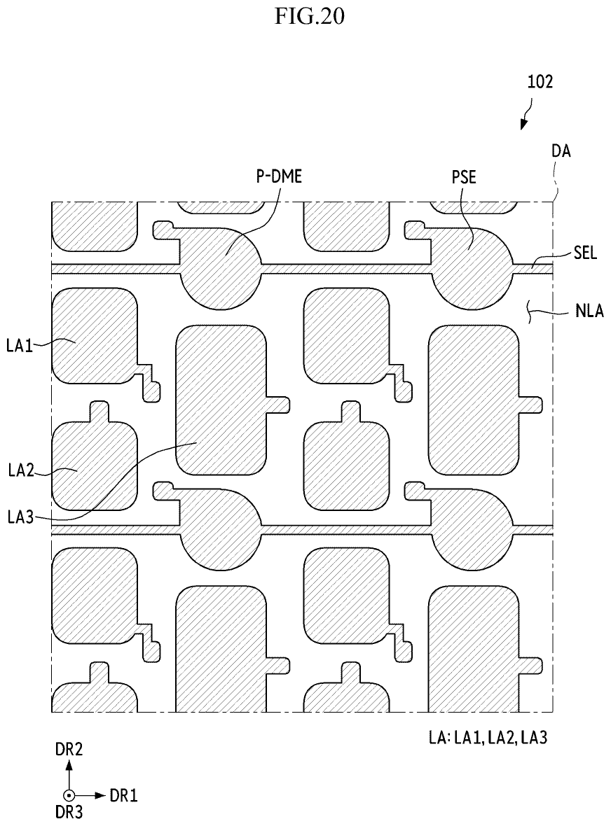

FIG. 20 is a layout view of a display panel 102 not including dummy electrodes.

Referring to FIG. 20, the display panel 102 may include pad-type dummy electrodes P-DME and auxiliary electrodes PSE in a non-emission area NLA.

The auxiliary electrodes PSE may have a circular shape or a polygonal shape such as a quadrangular shape in plan view. As described above, the auxiliary electrodes PSE, to which a second voltage is applied, may contact (e.g., directly contact) a common electrode to reduce a voltage drop (IR-drop) phenomenon of the common electrode.

The pad-type dummy electrodes P-DME and the auxiliary electrodes PSE may have the same size and the same shape.

The pad-type dummy electrodes P-DME and the auxiliary electrodes PSE may be connected by an auxiliary line SEL extending along the first direction DR1. The auxiliary line SEL may be electrically connected to a power line to which the second voltage ELVSS is provided and thus may provide the second voltage (e.g., low potential voltage). For example, the auxiliary electrodes PSE may receive the second voltage through the auxiliary line SEL.

A light emitting layer LEL (see FIG. 11) may be disposed on upper surfaces of the pad-type dummy electrodes P-DME, like the pixel electrode PXE of FIG. 11. However, unlike the pixel electrode PXE, the pad-type dummy electrodes P-DME may not be connected to a light emitting pixel driver EPD (see FIG. 10).

Since the light emitting layer LEL is disposed on the upper surfaces of the pad-type dummy electrodes P-DME, the pad-type dummy electrodes P-DME, unlike the auxiliary electrodes PSE, may not directly contact the common electrode CME. Therefore, the pad-type dummy electrodes P-DME may not affect a reduction in the voltage drop (IR-drop) phenomenon of the common electrode CME.

However, since each of the pad-type dummy electrodes P-DME has an increased overlap area with the common electrode, it may cause a random pixel failure.

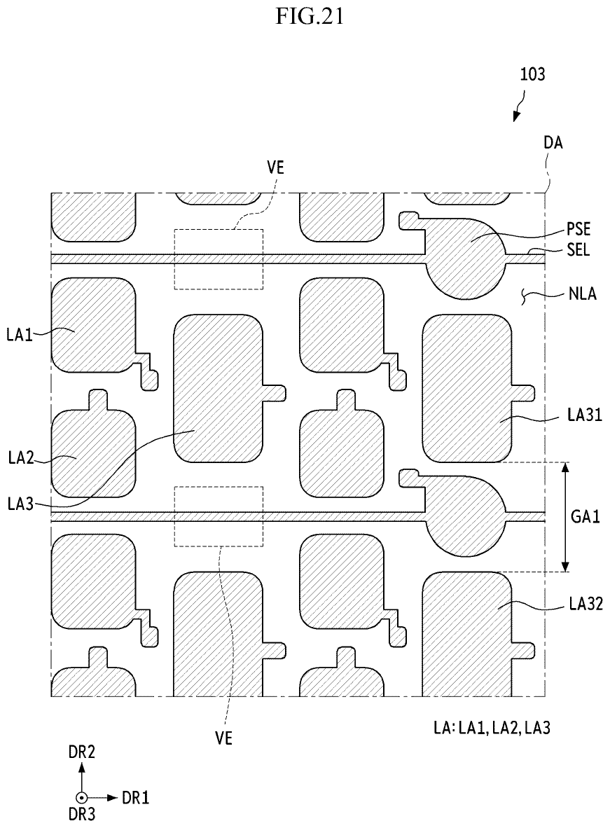

FIG. 21 is a layout view of a display panel 103 not including dummy electrodes.

The display panel 103 illustrated in FIG. 21 shows an embodiment in which the pad-type dummy electrodes P-DME are removed from the embodiment described above with reference to FIG. 20.

The display panel may include auxiliary electrodes PSE and dummy electrodes DME disposed in a part of a non-emission area NLA between emission areas LA.

A first gap area GA1 of a first width may be disposed between two or more third emission areas LA31 and LA32 parallel to each other in the second direction DR2 among third emission areas LA3. For example, the non-emission area NLA may include the first gap area GA1 disposed with the first width between two or more third emission areas LA31 and LA32 parallel to each other in the second direction DR2.

The auxiliary electrodes PSE may be disposed in the first gap area GA1.

The auxiliary electrodes PSE may be disposed only in a part of each first gap area GA1 of the display panel 103. For example, vacant areas VE in which the auxiliary electrodes PSE are not disposed may be formed in each first gap area GA1.

In case that the auxiliary electrodes PSE are disposed only in a part of each first gap area GA1 as described above, the blank areas VE may be seen in case that the display panel 103 emits light.

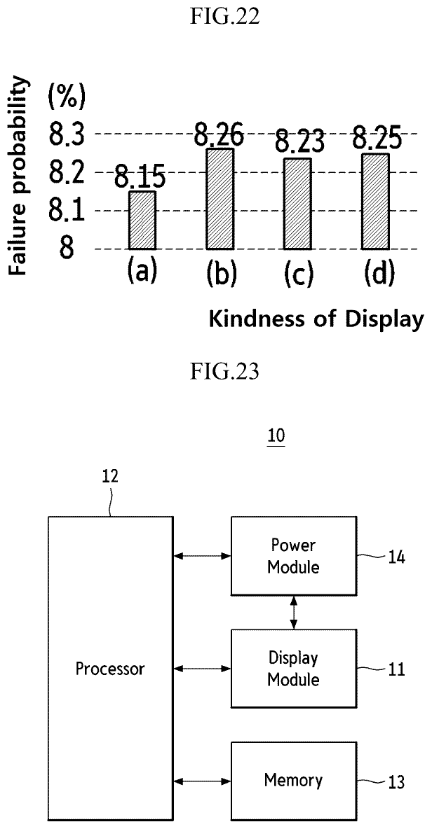

FIG. 22 is a graph illustrating the probability of random pixel failure in various embodiments. (a) through (d) of FIG. 22 are display panels which are the same in size and other performances except for the arrangement of auxiliary electrodes and dummy electrodes.

In FIG. 22, (a) shows the random pixel failure probability of a display panel in which auxiliary electrodes and dummy electrodes are not formed in all gap areas.

(b) shows the random pixel failure probability of a display panel in which auxiliary electrodes are formed in all gap areas.

(c) and (d) show the random pixel failure probabilities of display panels in which auxiliary electrodes and dummy electrodes are formed in gap areas in a ratio of about 1:1 as described above with reference to FIG. 9. (c) is a case in which the auxiliary electrodes have a line width of about 6 μm, and (d) is a case in which the auxiliary electrodes have a line width of about 12 μm.

As illustrated in FIG. 22, the random failure probability of the display panel (a) in which the auxiliary electrodes and the dummy electrodes are not formed is 8.15%, which is most advantageous in terms of random pixel failure. However, for example, a voltage drop of a common electrode cannot be prevented.

On the other hand, the random failure probability of the display panel (b) in which the auxiliary electrodes are formed in all gap areas is 8.26%, which is a highest random pixel failure probability.

The random failure probabilities of the display panels (c) and (d) in which the dummy electrodes are formed are 8.23% and 8.25%, respectively, which are lower than that of the display panel (b).

In conclusion, in case that dummy electrodes and auxiliary electrodes are formed together in a non-display area of a display panel, it is possible to prevent a voltage drop of a common electrode of the display panel while reducing random failures of the display panel.

A display device according to embodiments may be applied to various electronic devices. An electronic device according to an embodiment includes the display device described above and may further include modules or devices having other additional functions, in addition to the display device.

The display device according to an embodiment may be applied to various electronic devices. The electronic device according to an embodiment includes the display device described above, and may further include modules or devices having additional functions in addition to the display device.

According to a display device according to an embodiment, random pixel failures may be reduced by making an overlap area between a dummy electrode and a common electrode smaller than an overlap area between an auxiliary electrode and the common electrode.

For example, the dummy electrode may be formed in a ring shape (or loop shape) so that an area where the dummy electrode is disposed cannot be seen.

FIG. 23 is a block diagram of an electronic device according to an embodiment.

Referring to FIG. 23, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. In case that the processor 12 executes an application stored in the memory 13, an image data signal and/or an input control signal is transmitted to the display module 11, and the display module 11 may process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 11 according to an embodiment may be included in the display device 10 according to an embodiments. For example, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

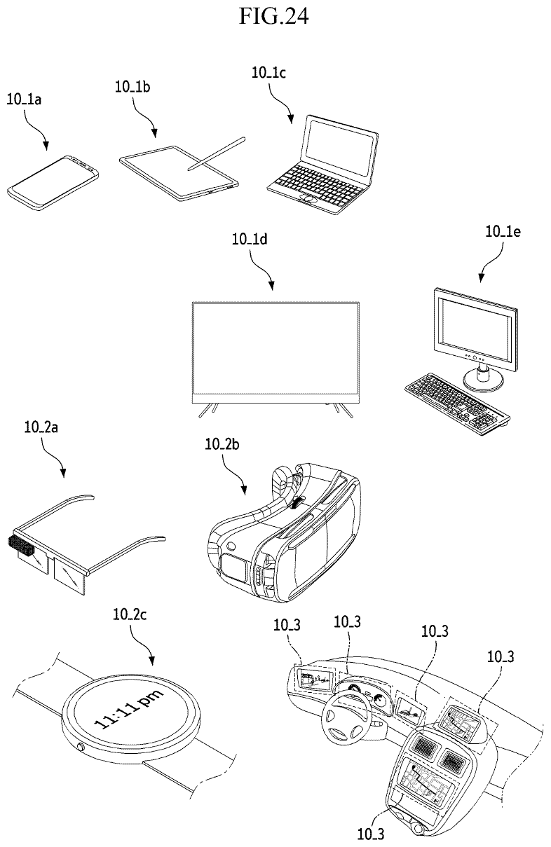

FIG. 24 is a schematic diagram of an electronic device according to various embodiments.

Referring to FIG. 24, various electronic devices to which display devices 10 according to embodiments are applied may include not only image display electronic devices such as a smart phone 10_1a, a tablet personal computer (PC) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (CID) and a room mirror display arranged on a dashboard, center fascia, and dashboard of an automobile.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate;
a circuit layer disposed on the substrate;
a pixel electrode disposed on the circuit layer in an emission area;
an auxiliary electrode disposed on the circuit layer in a non-emission area and spaced apart from the pixel electrode;
a dummy electrode disposed on the circuit layer in the non-emission area and spaced apart from the auxiliary electrode;
a light emitting layer disposed on the pixel electrode, the auxiliary electrode and the dummy electrode and comprising openings overlapping the auxiliary electrode; and
a common electrode disposed on the light emitting layer and electrically connected to the auxiliary electrode through the openings,
wherein the dummy electrode has a loop shape having a first line width.

2. The display device of claim 1, wherein the first line width is in a range of about 6 μm to about 12 μm.

3. The display device of claim 1, wherein
the dummy electrode has an inner diameter and an outer diameter, and
the outer diameter of the dummy electrode is substantially equal to a diameter of the auxiliary electrode.

4. The display device of claim 1, wherein the dummy electrode and the auxiliary electrode are disposed on a same layer.

5. The display device of claim 4, wherein the dummy electrode and the auxiliary electrode are arranged in a first direction and a second direction and are alternately disposed in the first direction.

6. The display device of claim 5, further comprising:
an auxiliary line extending along the first direction and connecting the dummy electrode and the auxiliary electrode.

7. The display device of claim 6, wherein the auxiliary line, the dummy electrode, and the auxiliary electrode are disposed in the same layer.

8. The display device of claim 4, wherein the pixel electrode, the dummy electrode, and the auxiliary electrode are disposed on a same layer.

9. The display device of claim 1, wherein an area of the dummy electrode is smaller than an area of the auxiliary electrode.

10. The display device of claim 1, wherein an overlap area between the dummy electrode and the common electrode is smaller than an overlap area between the auxiliary electrode and the common electrode.

11. The display device of claim 1, wherein a ratio of the number of dummy electrodes to the number of auxiliary electrodes is about 1:1.

12. The display device of claim 1, wherein
the dummy electrode has an inner diameter and an outer diameter,
the outer diameter of the dummy electrode defines an opening area, and
the circuit layer, the light emitting layer and the common electrode sequentially overlap in the opening area.

13. The display device of claim 1, wherein
a portion of the auxiliary electrode is exposed by the openings of the light emitting layer, and
the common electrode is disposed on the exposed portion of the auxiliary electrode.

14. The display device of claim 1, wherein
the pixel electrode is electrically connected to a first voltage line, and
the auxiliary electrode is electrically connected to a second voltage line which is a lower potential voltage than a first voltage.

15. The display device of claim 9, further comprising:
an encapsulation layer disposed on the common electrode,
wherein the encapsulation layer comprises a plurality of encapsulating inorganic layers and at least one encapsulating organic layer disposed between the plurality of encapsulating inorganic layers.

16. A method of manufacturing a display device, the method comprising:
forming a pixel electrode, an auxiliary electrode, a dummy electrode and an auxiliary line on a circuit layer disposed on a substrate and forming the dummy electrode in a loop shape;
forming a pixel defining layer between the pixel electrode, the auxiliary electrode, and the dummy electrode;
forming a light emitting layer on the pixel electrode, the auxiliary electrode, and the dummy electrode;
forming an opening area through a laser drilling process on a portion of the light emitting layer on the auxiliary electrode; and
forming a common electrode on the pixel electrode, the auxiliary electrode, and the dummy electrode,
wherein the dummy electrode and the common electrode are electrically connected through the opening area.

17. The method of claim 16, wherein in the forming of the pixel electrode, the auxiliary electrode, the dummy electrode and the auxiliary line on the circuit layer disposed on the substrate and the forming of the dummy electrode in the loop shape, a conductive material is deposited on the entire surface of the circuit layer and selectively patterned using a photolithography method to simultaneously form the pixel electrode, the auxiliary electrode, the dummy electrode, and the auxiliary line.

18. The method of claim 16, wherein in the forming of the dummy electrode in the loop shape, the dummy electrode has a first line width, and the first line width is in a range of about 6 μm to about 12 μm.

19. The method of claim 16, further comprising:
forming an encapsulation layer on the common electrode,
wherein the encapsulation layer comprises a plurality of encapsulating inorganic layers and at least one encapsulating organic layer disposed between the plurality of encapsulating inorganic layers.

20. An electronic device displaying an image, the electronic device comprising:
a memory;
a display device; and
a processor connected to the memory and the display device, the processor that executes commands included in the memory,
wherein the display device comprises:
a substrate;
a circuit layer disposed on the substrate;
a pixel electrode disposed on the circuit layer in a first area;
an auxiliary electrode disposed on the circuit layer in a second area and spaced apart from the pixel electrode;
a dummy electrode disposed on the circuit layer in a third area and spaced apart from the auxiliary electrode;
an organic layer disposed on the pixel electrode, the auxiliary electrode and the dummy electrode and comprising a plurality of openings overlapping the auxiliary electrode; and
a common electrode disposed on the organic layer and electrically connected to the auxiliary electrode through the openings,
wherein the dummy electrode has a loop shape having a first line width.
